(19) United States
(12) Patent Application Publication
(10) Pub. No.: US 2025/0040155 A1
(43) Pub. Date: Jan. 30, 2025

(54) CROSS-POINT OVONIC MEMORY DEVICE HAVING DIFFERENT SIZE ELECTRODES AND METHOD OF MAKING THE SAME

(71) Applicant: WESTERN DIGITAL TECHNOLOGIES, INC.,, SAN JOSE, CA (US)

(72) Inventors: Lei WAN, San Jose, CA (US); Michael Nicolas Albert TRAN, San Jose, CA (US); Hans J. RICHTER, Palo Alto, CA (US)

(21) Appl. No.: 18/499,325

(22) Filed: Nov. 1, 2023

Related U.S. Application Data
(63) Continuation-in-part of application No. 18/358,768, filed on Jul. 25, 2023.

(51) Int. Cl. H10B 99/00

(52) U.S. Cl. CPC H10B 99/10

(57) ABSTRACT

A memory device includes an ovonic memory element. The ovonic memory element contains a first electrode, a second electrode, and an ovonic threshold switching material portion located between the first electrode and the second electrode. A first surface of the first electrode that contacts a first surface of the ovonic threshold switching material portion has a greater area than a first surface of the second electrode that contacts a first segment of a second surface of the ovonic threshold switching material portion.

### RELATED APPLICATIONS

This application is a continuation-in-part (CIP) application of U.S. Application Ser. No. 18/358,768 filed on Jul. 25, 2023, the entire contents of which are incorporated herein by reference.

### FIELD

The present disclosure relates generally to the field of ovonic memory devices, and particularly to a cross-point ovonic memory device having different size electrodes and methods of manufacturing the same.

### BACKGROUND

A random access memory device is a memory device containing memory cells that allow random access, e.g., access to any selected memory cell upon a command for reading the contents of the selected memory cell. The memory cells of the random access memory device may be arranged in a cross-point configuration, where a bit memory cell resides at every intersection of a bit line and a word line.

### SUMMARY

According to an aspect of the present disclosure, a memory device includes an ovonic memory element. The ovonic memory element contains a first electrode, a second electrode, and an ovonic threshold switching material portion located between the first electrode and the second electrode. A first surface of the first electrode that contacts a first surface of the ovonic threshold switching material portion has a greater area than a first surface of the second electrode that contacts a first segment of a second surface of the ovonic threshold switching material portion.

According to another aspect of the present disclosure, a method of forming a memory device comprises forming first electrically conductive lines laterally extending along a first horizontal direction; forming a first electrode layer over the first electrically conductive lines; forming an ovonic threshold switching material layer over the first electrode layer; forming a second electrode layer over the ovonic threshold switching material layer; patterning the second electrode layer into a two-dimensional array of second electrodes; forming sidewall spacers on at least one sidewall of the second electrodes; patterning the ovonic threshold switching material layer and the first electrode layer into a two-dimensional array of ovonic threshold switching material portions and first electrodes using the two-dimensional array of second electrodes and the sidewall spacers as a mask; and forming second electrically conductive lines laterally extending along a second horizontal direction over the two-dimensional array of ovonic threshold switching material portions.

According to another aspect of the present disclosure, a method of forming a device structure comprises: forming a first alternating stack of first insulating rails and first electrically conductive rails over a substrate, wherein the first insulating rails and first electrically conductive rails extend along a first direction, and are interlaced along a second direction such that the first insulating rails and the first electrically conductive rails alternate along the second direction, and wherein the first alternating stack comprises a first surface and a second surface that are spaced from each other along a third direction that is perpendicular to the first direction and the second direction; forming a first ovonic memory strip over the first alternating stack, wherein the first ovonic memory strip comprises a first ovonic memory strip segment extending along the second direction and in contact with the first surface of the first alternating stack, and further comprises a second ovonic memory strip segment extending along the second direction and in contact with the second surface; and forming a first conductive line over the first ovonic memory strip, wherein the first conductive line comprises a first conductive line segment extending along the second direction and in contact with the first ovonic memory strip segment, and further comprises a second conductive line segment extending along the second direction and in contact with the second ovonic memory strip segment.

According to yet another aspect of the present disclosure, a memory device comprising an ovonic memory element is provided. The ovonic memory element comprises: a first electrode; a second electrode vertically spaced from the first electrode; and an ovonic threshold switching material portion located between the first electrode and the second electrode, wherein a top surface of the first electrode that contacts a bottom surface of the ovonic threshold switching material portion has a greater lateral dimension along a first horizontal direction than a bottom surface of the second electrode that contacts a first segment of a top surface of the ovonic threshold switching material portion.

According to an aspect of the present disclosure, an ovonic memory element includes a first electrode, a second electrode, and an ovonic threshold switching material portion located between the first electrode and the second electrode. A first surface of the ovonic threshold switching material portion facing the first electrode is wider than an opposing second surface of the ovonic threshold switching material portion facing the second electrode.

According to yet another aspect of the present disclosure, a method of forming a memory device is provided. The method comprises: forming first electrically conductive lines laterally extending along a first horizontal direction; forming an ovonic threshold switching material layer over the first electrically conductive lines; patterning the ovonic threshold switching material layer into a two-dimensional array of ovonic threshold switching material portions having a respective shape of a frustum; and forming second electrically conductive lines laterally extending along a second horizontal direction over the two-dimensional array of ovonic threshold switching material portions.

### BRIEF DESCRIPTION OF THE DRAWINGS

FIG. 1 is a schematic diagram of a memory device including ovonic memory cells of the present disclosure in an array configuration.

FIG. 2A illustrates a perspective view of a first exemplary multi-tier ovonic memory array and a magnified view of an ovonic memory cell.

FIG. 2B illustrates a perspective view of a second exemplary multi-tier ovonic memory array and a magnified view of an ovonic memory cell.

FIGS. 3A-3F are sequential perspective views of a first exemplary structure during formation of a two-dimensional array of ovonic memory cells according to a first embodiment of the present disclosure.

FIGS. 4A-4D are sequential perspective views of a second exemplary structure during formation of a two-dimensional array of ovonic memory cells according to a second embodiment of the present disclosure.

FIGS. 5A-5G are sequential perspective views of a third exemplary structure during formation of a two-dimensional array of ovonic memory cells according to a third embodiment of the present disclosure.

FIG. 6 schematically illustrates variations in DVth/Vth for various shapes of ovonic threshold switching material portions.

FIGS. 7A-7I are sequential perspective views of a fourth exemplary structure during formation of a two-dimensional array of ovonic memory cells according to a fourth embodiment of the present disclosure.

FIGS. 8A-8D and 8F are sequential perspective views of a fifth exemplary structure during formation of a two-dimensional array of ovonic memory cells according to a fifth embodiment of the present disclosure. FIG. 8E is a perspective view of the fifth exemplary structure after the processing steps of FIG. 8D in which dielectric spacers are omitted for illustrative purposes.

FIGS. 9A-9E are sequential perspective views of a sixth exemplary structure during formation of a three-dimensional array of ovonic memory cells according to a sixth embodiment of the present disclosure.

FIG. 9F is a vertical cross-sectional view of the sixth exemplary structure along the vertical plane F in FIG. 9E.

FIG. 9G is a vertical cross-sectional view of the sixth exemplary structure along the vertical plane G in FIG. 9E.

### DETAILED DESCRIPTION

As discussed above, the embodiments of the present disclosure are directed to a cross-point ovonic memory device and methods of manufacturing the same, the various aspects of which are discussed herein in detail. In self-selecting cross-point memory devices based on ovonic threshold switches, the threshold voltage of an ovonic material has a small hysteresis effect, and can increase if a previously applied electrical pulse (e.g., programming pulse) had an opposite polarity relative to a subsequently applied electrical pulse (e.g., read pulse). In other words, the absolute value of the threshold voltage of the device during a read voltage pulse increases if the previous programming voltage pulse had an opposite polarity from the read voltage pulse. This phenomenon is utilized in a memory device employing the ovonic threshold switch (OTS) material itself as a memory material, i.e., an OTS-only memory, rather than using the OTS material as a selector element for another type of memory material, such as a magnetic memory material. Such an OTS-only memory device may provide device scalability and possible additional advantages. However, the OTS-only memory device has a narrow memory window, i.e., a small difference in the threshold voltages between a forward programming condition (in which a previously applied programming pulse has the same polarity as the sensing pulse) and a reverse programming condition (in which a previously applied programming pulse has an opposite polarity relative to the sensing pulse). A useful metric for determining operability of the OTS-only memory is A Vth/Vth which is the ratio of the difference between the threshold voltages under the reverse programming condition and the threshold voltages under the forward programming condition, to the threshold voltage under the forward programming condition. In one embodiment, A Vth may be the difference between Vth+/− and Vth+/+, where Vth+/− is the threshold voltage going from a positive voltage pulse to a negative voltage pulse, and Vth+/+ is the threshold voltage going from a positive voltage pulse to another positive voltage pulse. In this case, ΔVth/Vth={(Vth+/−)−(Vth+/+)}/(Vth+/+). Prior art OTS-only devices exhibit values of ΔVth/Vth of about 12% or less. The embodiments of the present disclosure provide an OTS-only device with an improved value of ΔVth/Vth.

The drawings are not drawn to scale. Multiple instances of an element may be duplicated where a single instance of the element is illustrated, unless absence of duplication of elements is expressly described or clearly indicated otherwise. Same reference numerals refer to the same element or to a similar element. Elements having the same reference numerals are presumed to have the same material composition unless expressly stated otherwise. Ordinals such as “first,” “second,” and “third” are employed merely to identify similar elements, and different ordinals may be employed across the specification and the claims of the instant disclosure. As used herein, a first element located “on” a second element can be located on the exterior side of a surface of the second element or on the interior side of the second element. As used herein, a first element is located “directly on” a second element if there exist a physical contact between a surface of the first element and a surface of the second element. As used herein, an “in-process” structure or a “transient” structure refers to a structure that is subsequently modified.

As used herein, a “layer” refers to a material portion including a region having a thickness. A layer may extend over the entirety of an underlying or overlying structure, or may have an extent less than the extent of an underlying or overlying structure. Further, a layer may be a region of a homogeneous or inhomogeneous continuous structure that has a thickness less than the thickness of the continuous structure. For example, a layer may be located between any pair of horizontal planes between, or at, a top surface and a bottom surface of the continuous structure. A layer may extend horizontally, vertically, and/or along a tapered surface. A substrate may be a layer, may include one or more layers therein, and/or may have one or more layer thereupon, thereabove, and/or therebelow.

As used herein, a “layer stack” refers to a stack of layers. As used herein, a “line” or a “line structure” refers to a layer that has a predominant direction of extension, i.e., having a direction along which the layer extends the most.

As used herein, a “conductive material” refers to a material having electrical conductivity greater than 1.0×10⁵ S/cm. As used herein, an “insulating material” or a “dielectric material” refers to a material having electrical conductivity less than 1.0×10⁻⁶ S/cm. As used herein, a “metallic material” refers to an electrically conductive material including at least one metal element therein. All measurements for electrical conductivities are made at the standard condition.

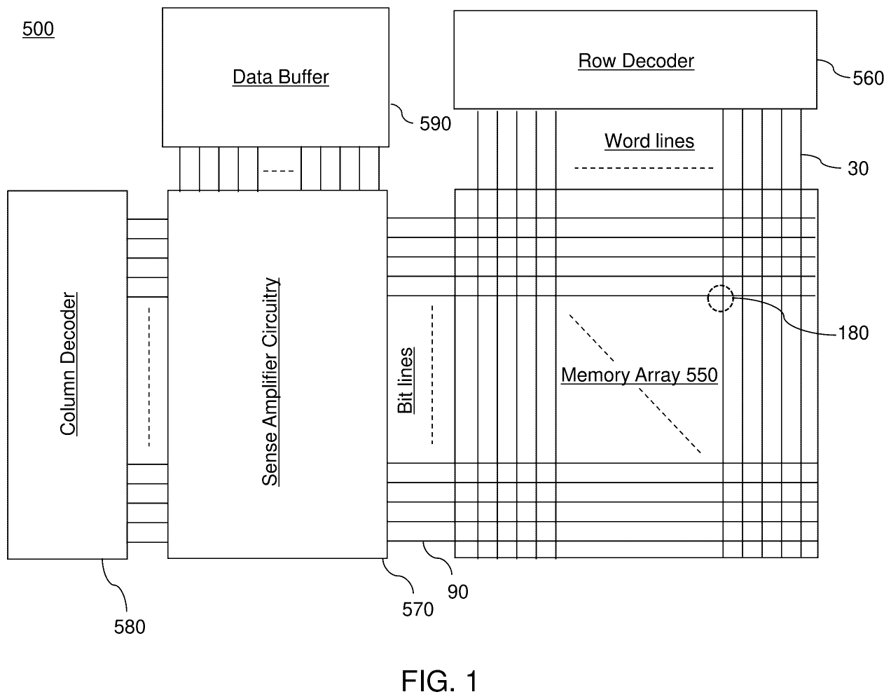

Referring to FIG. 1, a schematic diagram is shown for an ovonic memory device including an array of ovonic memory cells 180 of an embodiment of the present disclosure in an array configuration. The ovonic memory device can be configured as a random access memory (RAM) device 500.

The RAM device 500 of an embodiment of the present disclosure includes a memory array region 550 containing an array of the respective ovonic memory cells 180 located at the intersection of the respective word lines (which may comprise first electrically conductive lines 30 as illustrated or as second electrically conductive lines 90 in an alternate configuration) and bit lines (which may comprise second electrically conductive lines 90 as illustrated or as first electrically conductive lines 30 in an alternate configuration). The RAM device 500 may also contain a row decoder 560 connected to the word lines, a sense circuitry 570 (e.g., a sense amplifier and other bit line control circuitry) connected to the bit lines, a column decoder 580 connected to the bit lines, and a data buffer 590 connected to the sense circuitry. Multiple instances of the ovonic memory cells 180 are provided in an array configuration that forms the RAM device 500. As such, each of the ovonic memory cells 180 can be a two-terminal device including a respective first electrode and a respective second electrode. It should be noted that the location and interconnection of elements are schematic and the elements may be arranged in a different configuration. Further, an ovonic memory cell 180 may be manufactured as a discrete device, i.e., a single isolated device. Configurations of the ovonic memory cells 180 are described in more detail below.

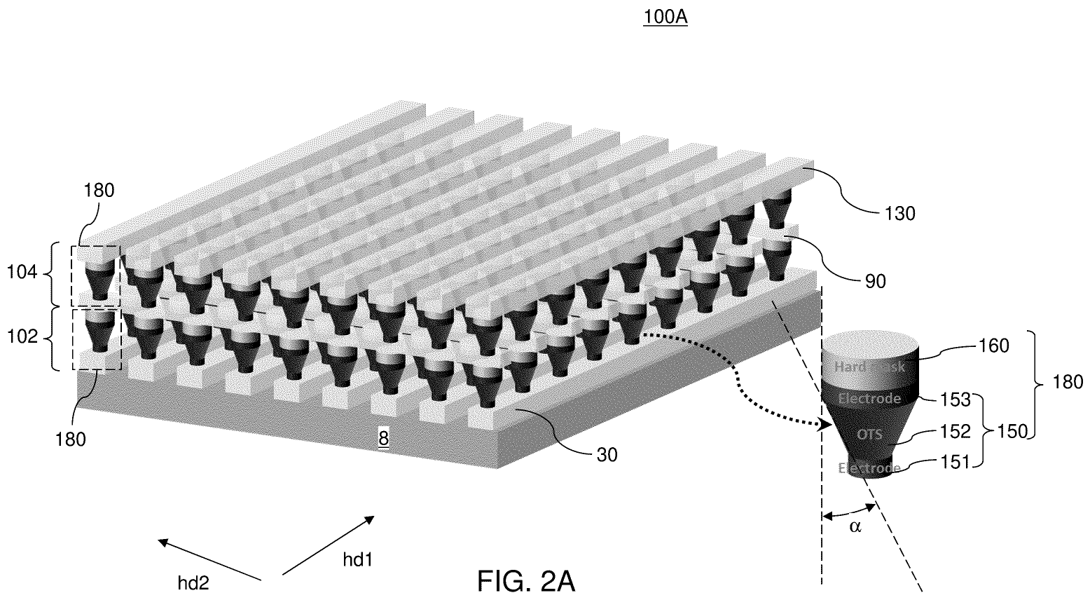

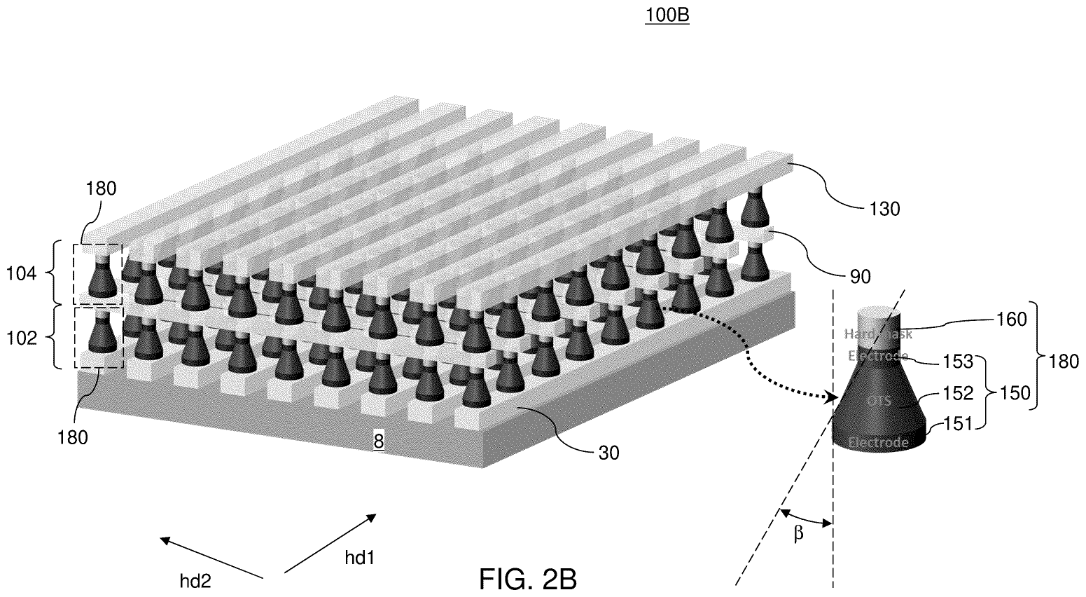

Referring to FIGS. 2A and 2B, a first exemplary multi-tier ovonic memory array 100A and a second exemplary multi-tier ovonic memory array 100B are illustrated, respectively, according to first and second embodiments of the present disclosure, respectively. Each multi-tier memory array may comprise first electrically conductive lines 30 laterally extending along a first horizontal direction hd1 over a substrate 8, second electrically conductive lines 90 laterally extending along a second horizontal direction hd2 which may be perpendicular to the first horizontal direction hd1, and third electrically conductive lines 130 laterally extending along the first horizontal direction hd1. An ovonic memory cell 180 can be located at each cross-point of a respective one of the first electrically conductive lines 30 and a respective one of the second electrically conductive lines 90 to provide the first-tier ovonic memory array 102. An ovonic memory cell 180 can be located at each cross-point a respective one of the second electrically conductive lines 90 and a respective one of the third electrically conductive lines 130 to provide a second-tier ovonic memory array 104 that overlies the first-tier ovonic memory array 102.

Each ovonic memory cell 180 comprises a vertical stack of an ovonic memory element 150 and an optional metallic pillar structure 160. The ovonic memory element 150 may comprise a vertical stack including a first electrode 151, a second electrode 153, and an ovonic threshold switching material portion 152 located between the first electrode 151 and the second electrode 153. The surface of the ovonic threshold switching material portion 152 facing one of the electrodes (151, 153) is wider than the opposing surface of the ovonic threshold switching material portion 152 facing the other one of the electrodes (153, 151). In other words, if the vertical stack includes, from bottom to top relative to the substrate 8, the first electrode 151, the ovonic threshold switching material portion 152, and the second electrode 153, then the wider surface of the ovonic threshold switching material portion 152 may be the top surface facing the overlying second electrode 153 or the bottom surface facing the underlying first electrode 151.

In one embodiment, the ovonic threshold switching material portion 152 has a shape of a frustum. A frustum is a three-dimensional geometrical shape that is derived from a cone or pyramidal shape having any planar base shape in which the tip portion of the cone or pyramidal shape is cut off by a plane parallel to the plane of the base. As such, a frustum may have a circular, elliptical, or polygonal horizontal cross-sectional shape. The wider base may be located above or below the narrower part of the frustrum located in the cut off plane, relative to the substrate 8 supporting the memory element 150.

Each frustum shape of the ovonic memory cell 180 may have a variable horizontal cross-sectional shape that increases in area with a vertical distance from the substrate 8 as illustrated in FIG. 2A, or may have a variable horizontal cross-sectional shape that decreases in area with a vertical distance from the substrate 8 as illustrated in FIG. 2B. Accordingly, the sidewall of each ovonic threshold switching material portion 152 may have a negative taper angle a as illustrated in FIG. 2A, or may have a positive taper angle b as illustrated in FIG. 2B.

As used herein, a positive taper angle is a taper angle that causes a structure become gradually narrower with an increase in an upward vertical distance (i.e., a vertical distance from an underlying horizontal plane), and a negative taper angle is a taper angle that causes a structure to become gradually wider with an increase in the upward vertical distance.

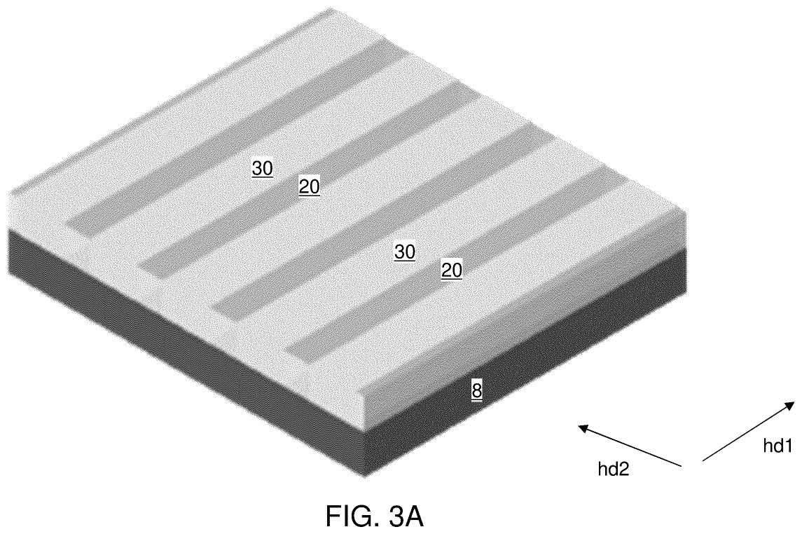

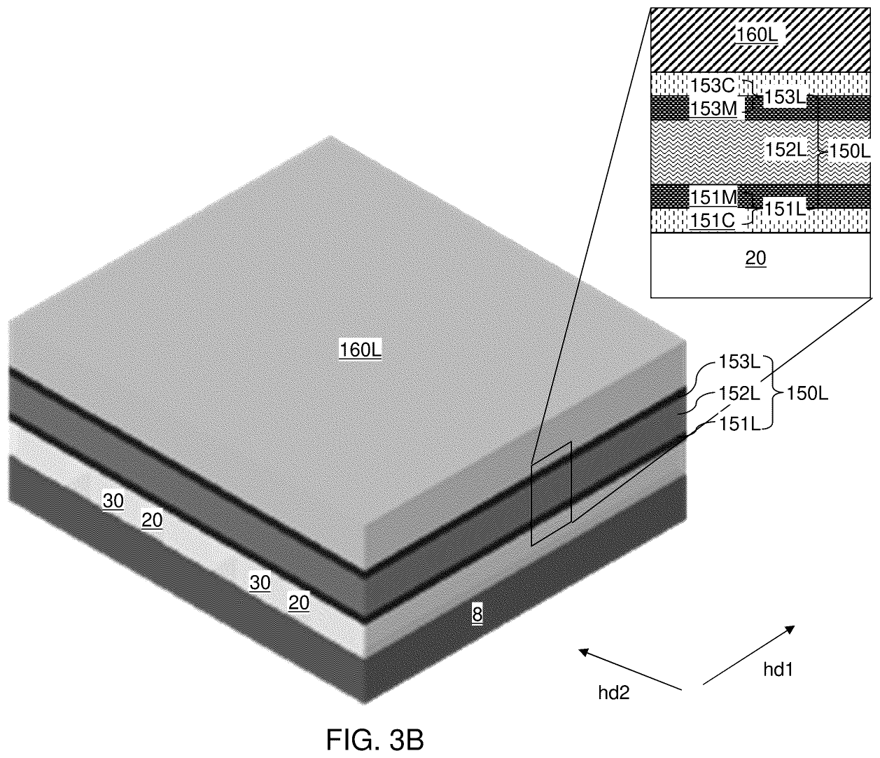

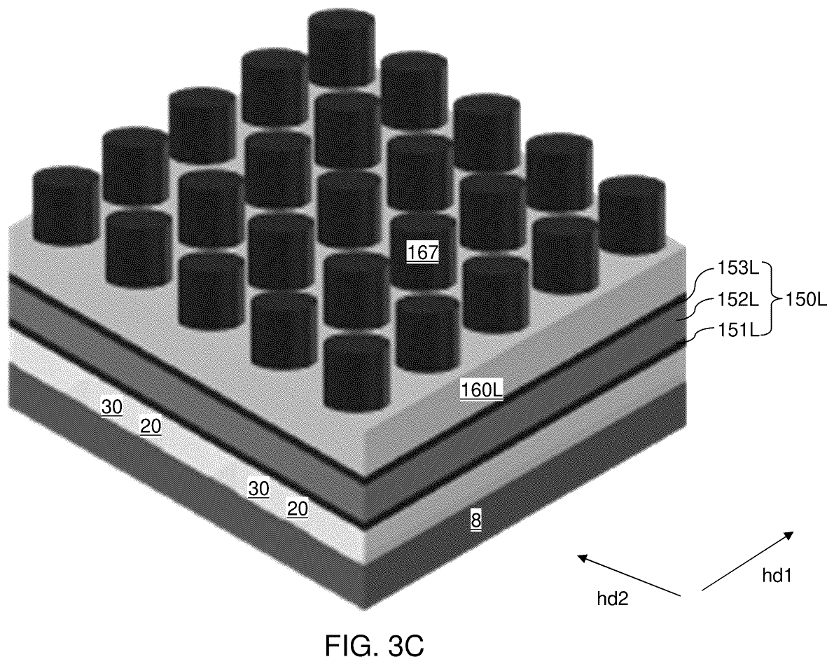

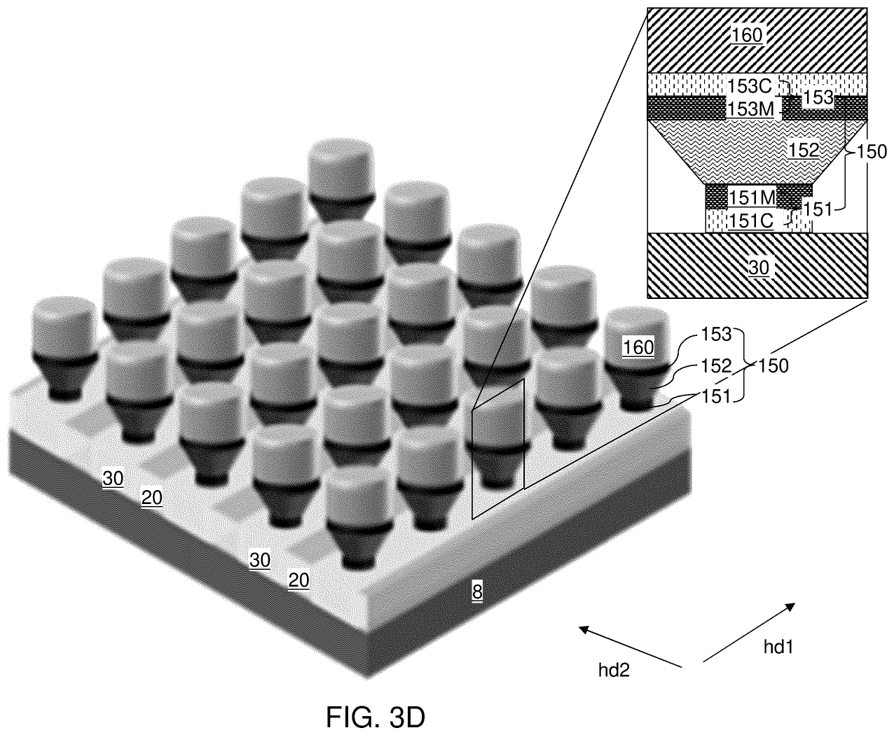

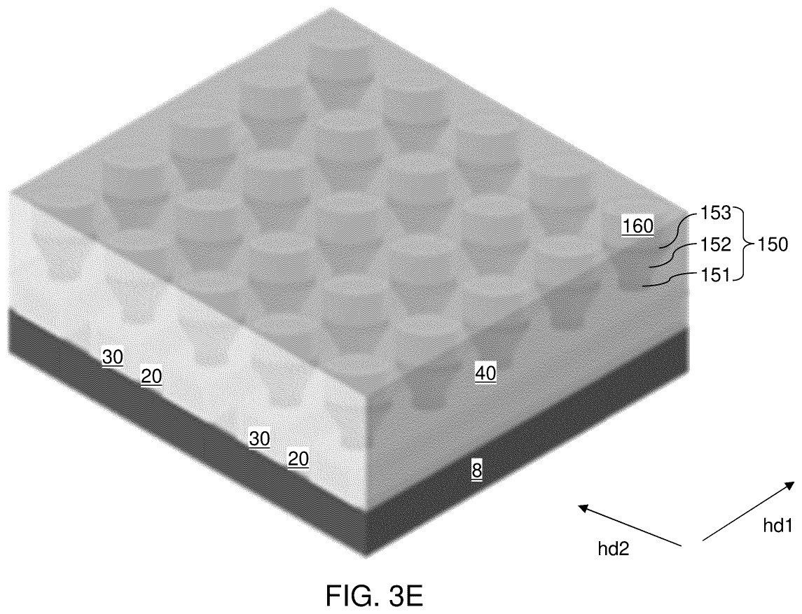

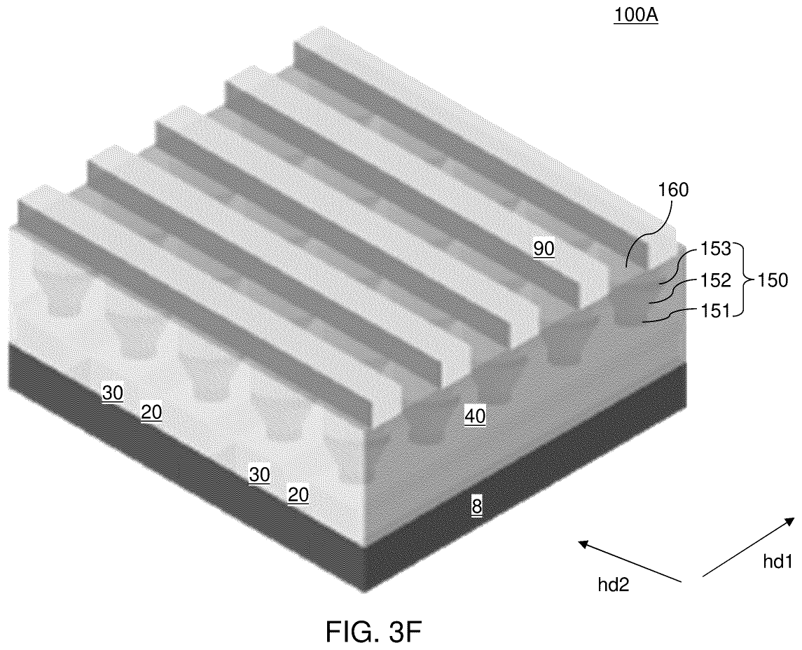

Referring to FIGS. 3A-3F, a first exemplary structure is illustrated during formation of the two-dimensional array 100A of ovonic memory cells 180 of FIG. 2A according to the first embodiment of the present disclosure.

Referring to FIG. 3A, the first exemplary structure includes a substrate 8 having an insulating top surface. The substrate 8 may comprise a combination of a handle substrate (not expressly shown) and an insulating cap layer (not expressly shown). Alternatively, the substrate 8 may comprise a semiconductor substrate (such as a commercially available silicon wafer), semiconductor devices (such as field effect transistors of the driver circuit) formed on the semiconductor substrate, and metal interconnect structures embedded in dielectric material layers overlying the semiconductor devices and providing electrical connection among the semiconductor devices and between the semiconductor devices and the array 100A of ovonic memory cells 180 to be subsequently formed.

First electrically conductive line 30 can be formed on an insulating top surface of the substrate 8. In one embodiment, the first electrically conductive lines 30 can be formed by depositing and patterning a first electrically conductive layer over the insulating top surface of the substrate 8. An insulating material can be deposited between neighboring pairs of first electrically conductive lines 30 and then planarized to form first insulating rails 20. Alternatively, the first electrically conductive lines 30 may be formed by a damascene process which includes depositing an insulating matrix layer over the substrate 8, patterning the insulating matrix layer to form first line trenches that laterally extend along the first horizontal direction hd1, filling the first line trenches with at least one electrically conductive material, and removing portions of the electrically conductive material from above the horizontal plane including the top surface of the insulating matrix layer. Remaining portions of the at least one electrically conductive material filing the first line trenches constitute the first electrically conductive lines 30. The remaining portions of the insulating matrix layer comprise first insulating rails 20.

The width of the first electrically conductive lines 30 may be in a range from 20 nm to 300 nm, although lesser and greater widths may also be employed. The spacing between neighboring pairs of first electrically conductive lines 30 may be in a range from 30 nm to 300 nm, although lesser and greater spacings may also be employed. In one embodiment, the first electrically conductive lines 30 may function as word lines for the first-tier ovonic memory array 102.

Referring to FIG. 3B, a stack of blanket (unpatterned) layers can be deposited over a laterally alternating sequence of first electrically conductive lines 30 and first insulating rails 20. The stack of blanket layers comprise, for example, a first electrode material layer 151L, an ovonic threshold switching material layer 152L, a second electrode material layer 153L, and an optional metallic hard mask layer 160L. The combination of the first electrode material layer 151L, the ovonic threshold switching material layer 152L, and the second electrode material layer 153L is herein referred to as an ovonic memory layer 150L.

The first electrode material layer 151L includes at least one material that may be employed for first electrodes (such as the first electrodes 151 illustrated in FIGS. 2A and 2B). The ovonic threshold switching material layer 152L includes an ovonic threshold switching material. The second electrode material layer 153L includes at least one material that may be employed second electrodes (such as the second electrodes 153 illustrated in FIGS. 2A and 2B).

In one embodiment, the first electrode material layer 151L may optionally comprise a layer stack including at least one of a first carbon-based electrode material layer 151C and a first metallic material layer 151M formed on the first carbon-based electrode material layer 151C. In one embodiment, the second electrode material layer 153L may optionally comprise a layer stack including at least one of a second metallic material layer 153M and a second carbon-based electrode material layer 153C formed on the second metallic material layer 153M. In another embodiment, the first and/or the second metallic material layers (151M, 153M) may be omitted and the first and second electrode material layers (151L, 153L) may include only the respective first and second carbon-based electrode material layers (151C, 153C).

The first carbon-based electrode material layer 151C and the second carbon-based electrode material layer 153C within the-level material layers can include a respective carbon-based conductive material including carbon atoms at an atomic concentration greater than 50%. In one embodiment, the first carbon-based electrode material layer 151C and the second carbon-based electrode material layer 153C may include carbon atoms at an atomic concentration in a range from 50% to 100%, such as from 70% to 100% and/or from 80% to 100%. In one embodiment, each of first carbon-based electrode material layer 151C and the second carbon-based electrode material layer 153C comprises a respective material selected from diamond-like carbon (DLC), a carbon nitride material, and a carbon-rich conductive compound of carbon atoms and non-carbon atoms. Each of the first carbon-based electrode material layer 151C and the second carbon-based electrode material layer 153C may have a respective thickness in a range from 3 nm to 300 nm, although lesser and greater thicknesses may also be employed.

The first metallic material layer 151M and the second metallic material layer 153M can include a respective metallic material having electrical conductivity that is greater than the electrical conductivity of the carbon-based conductive materials of the first carbon-based electrode material layer 151C and the second carbon-based electrode material layer 153C. In one embodiment, the first metallic material layer 151M comprises a metallic material having electrical conductivity that is at least 10 times (which may be at least 30 times and/or at least 100 times and/or at least 1,000 times) the electrical conductivity of the carbon-based conductive material of first carbon-based electrode material layer 151C, and the second metallic material layer 153M comprises a second metallic material having electrical conductivity that is at least 10 times (which may be at least 30 times and/or at least 100 times and/or at least 1,000 times) the electrical conductivity of the carbon-based conductive material of the second carbon-based electrode material layer 153C.

Generally, each of the first metallic material layer 151M and the second metallic material layer 153M may comprise, and/or may consist essentially of, a high-conductivity metallic material that has a high electrical conductivity, and thus, is capable of functioning as a current-spreading material that prevents concentration of electrical current in the ovonic threshold switching material of the ovonic threshold switching material layer 152L. In one embodiment, the first metallic material layer 151M and/or the second metallic material layer 153M may comprise, and/or may consist essentially of, an elemental metal, a conductive metallic carbide, or a conductive metallic nitride. In one embodiment, the first metallic material layer 151M and/or the second metallic material layer 153M may comprise, and/or may consist essentially of, a respective elemental metal selected from ruthenium, niobium, molybdenum, tantalum, tungsten, or rhenium. In one embodiment, the first metallic material layer 151M and/or the second metallic material layer 153M may comprise, and/or may consist essentially of, a conductive metallic carbide, such as tungsten carbide. In one embodiment, the first metallic material layer 151M and/or the second metallic material layer 153M may comprise, and/or may consist essentially of, a conductive metallic nitride, such as tungsten nitride, titanium nitride, or tantalum nitride.

In one embodiment, the ovonic threshold switching material layer 152L can include an ovonic threshold switching material which exhibits non-linear electrical behavior. As used herein, an ovonic threshold switching material refers to a material that displays a non-linear resistivity curve under an applied external bias voltage such that the resistivity of the material decreases with the absolute magnitude of the applied external bias voltage greater than the absolute value of the threshold voltage. In one embodiment, the ovonic threshold switch material can comprise a chalcogenide material. The chalcogenide material may be a GeSeAs alloy, a GeSeAsTe alloy, a GeTeAs alloy, a GeSeTe alloy, a GeSe alloy, a SeAs alloy, a AsTe alloy, a GeTe alloy, a SiTe alloy, a SiAsTe alloy, or SiAsSe alloy. The chalcogenide material may be undoped or doped with at least one of N, O, C, P, Ge, As, Te, Se, In, or Si.

The metallic hard mask layer 160L comprises at least one electrically conductive material that may subsequently function as a hard mask material. The metallic hard mask layer 160L may comprise at least one metallic nitride material and/or at least one elemental metal. For example, the metallic hard mask layer 160L may comprise and/or may consist essentially of TiN, TaN, WN, MON, Ti, Ta, W, Mo, Co, Ru, etc.

Referring to FIG. 3C, a photoresist layer can be applied over the metallic hard mask layer 160L, and can be lithographically patterned to form a two-dimensional array of discrete photoresist material portions 167. The two-dimensional array of discrete photoresist material portions 167 may have a periodic pitch along the second horizontal direction hd2 that is the same as the pitch of the first electrically conductive lines 30 along the second horizontal direction hd2.

Referring to FIG. 3D, an anisotropic etch process can be performed to transfer the pattern of the two-dimensional array of discrete photoresist material portions 167 through the metallic hard mask layer 160L. The metallic hard mask layer 160L can be patterned into a two-dimensional array of metallic pillar structures 160. In one embodiment, the metallic pillar structures 160 may have a circular cylindrical shape or an elliptical cylindrical shape.

The anisotropic etch process may be continued with a suitable change in the etch chemistry to etch unmasked portions of the second electrode material layer 153L. The second electrode material layer 153L is patterned into a two-dimensional array of second electrodes 153. Each second electrode 153 may comprise a layer stack of a second metallic material layer 153M and an second carbon-based electrode material layer 153C overlying the second metallic material layer 153M. The two-dimensional array of discrete photoresist material portions 167 can be subsequently removed, for example, by ashing.

The ovonic threshold switching material layer 152L can be patterned by transferring the pattern in the two-dimensional array of metallic pillar structures 160 through the ovonic threshold switching material layer 152L. In one embodiment, the pattern in the two-dimensional array of metallic pillar structures 160 can be transferred through the ovonic threshold switching material layer 152L by performing an ion beam etching process. In one embodiment, a two-step ion-beam etching (IBE) process may be employed to pattern the ovonic threshold switching material layer 152L into a two-dimensional array of ovonic threshold switching material portions 152 each having a shape of a respective inverted conical frustum.

The two-step IBE process comprises a first IBE process (also referred to as a low-tilt-angle high-energy IBE process) in which a first high energy ion beam impinges onto the ovonic threshold switching material layer 152L at a first tilt angle relative to a vertical direction perpendicular to the top surface of the substrate 8. The first tilt angle may be in a range from 0 degree to 35 degrees, and the direction of the ion beam may be gradually azimuthally rotated by 360 degrees around the vertical direction during the first IBE process. In the first IBE process, the ion beam penetrates through the entire thickness of the ovonic threshold switching material layer 152L. The two-step IBE process further comprises a second IBE process (also referred to as a high-tilt-angle low-energy IBE process) in which a second lower energy ion beam than the first ion beam impinges onto the patterned discrete portions of the ovonic threshold switching material layer 152L at a second tilt angle relative to the vertical direction. The second tilt angle may be higher than the first tilt angle. For example, the second title angle may be in a range from 60 degrees to 80 degrees, and the direction of the ion beam may be gradually azimuthally rotated by 360 degrees around the vertical direction during the second IBE process. The patterned discrete portions of the ovonic threshold switching material layer 152L can be patterned into the shapes of the inverted frustums during the second IBE process to form the two-dimensional array of ovonic threshold switching material portions 152. The high tilt angle prevents re-deposition of etched materials from the ovonic threshold switching material layer 152L.

In an alternative embodiment, the inverted frustrum shaped ovonic threshold switching material portions 152 may be formed by a one step reactive ion etching process which includes undercutting. In other words, the reactive ion etching process conditions are selected to form the ovonic threshold switching material portions 152 with inclined sidewalls, as shown in FIG. 3D.

Another anisotropic etch process may be performed to etch unmasked portions of the first electrode material layer 151L. The combination of the arrays of the metallic pillar structures 160, the second electrodes 153, and the ovonic threshold switching material portions 152 may be employed as an etch mask for patterning the first electrode material layer 151L. The first electrode material layer 151L is patterned into a two-dimensional array of first electrodes 151. Each first electrode 151 may comprise a layer stack of a first metallic material layer 151M and a first carbon-based electrode material layer 151C underlying the first metallic material layer 151M.

Referring to FIG. 3E, at least one dielectric fill material, such as a combination of a silicon nitride liner and a silicon oxide fill material layer, can be deposited in the gaps among the arrays of the metallic pillar structures 160, the second electrodes 153, the ovonic threshold switching material portions 152, and the first electrodes 151. A suitable reflow process may optionally be performed to reduce, and/or eliminate, voids in the at least one dielectric fill material. A planarization process, such as a chemical mechanical polishing process, may be performed to remove portions of the at least one dielectric fill material from above the horizontal plane including the top surfaces of the metallic pillar structures 160. The remaining portion of the at least one dielectric fill material constitutes a dielectric fill material layer 40 that laterally surrounds the arrays of the metallic pillar structures 160, the second electrodes 153, the ovonic threshold switching material portions 152, and the first electrodes 151.

Referring to FIG. 3F, second electrically conductive lines 90 can be formed on the physically exposed surfaces of the metallic pillar structures 160. Each second electrically conductive line 90 can laterally extend along the second horizontal direction hd2, and may contact a respective column of metallic pillar structures 160 that extends along the second horizontal direction hd2. The pitch of the second electrically conductive lines 90 along the first horizontal direction hd1 may be the same as the pitch of the two-dimensional array of metallic pillar structures 160 along the first horizontal direction hd1. An insulating material (not shown) can be deposited between neighboring pairs of second electrically conductive lines 90 to form second insulating rails (not shown).

Alternatively, the second electrically conductive lines 90 may be formed by a damascene process which includes depositing an insulating matrix layer, patterning the insulating matrix layer to form second line trenches that laterally extend along the second horizontal direction hd2, filling the second line trenches with at least one electrically conductive material, and removing portions of the electrically conductive material from above the horizontal plane including the top surface of the insulating matrix layer. Remaining portions of the at least one electrically conductive material filing the second line trenches constitute the second electrically conductive lines 90. The remaining portions of the insulating matrix layer comprise second insulating rails (not shown).

The second electrically conductive lines 90 laterally extend along the second horizontal direction hd2, and each second electrode 153 in the two-dimensional array of memory cells contacts a respective one of the second electrically conductive lines 90. The second electrically conductive lines 90 may function as bit lines in the first-tier ovonic memory array 102.

In one embodiment, each second electrode 153 contacts a bottom surface of metallic pillar structure 160. Each metallic pillar structure 160 has a different area than a bottom surface of an underlying ovonic threshold switching material portion 152. In one embodiment, for each ovonic threshold switching material portion 152, a tapered surface of the ovonic threshold switching material portion 152 continuously extends from a top surface of the first electrode 151 to a bottom surface of the second electrode 153. In one embodiment, the ovonic threshold switching material portion 152 has a variable horizontal cross-sectional area that increases with a vertical distance from a horizontal plane including the top surfaces of the first electrodes 151. In one embodiment, the ovonic threshold switching material portions 152 have a respective circular or oval-shaped horizontal cross-sectional shape.

In one embodiment, each first electrode 151 comprises a layer stack including a first carbon-based electrode material layer 151C and a first metallic material layer 151M. In one embodiment, each second electrode 153 comprises a layer stack including a second metallic material layer 153M and a second carbon-based electrode material layer 153C. In one embodiment, each first electrode 151 comprises a first metallic surface in contact with a bottom surface of an ovonic threshold switching material portion 152.

In one embodiment, a two-dimensional array 100A of memory cells 180 is provided. Each of the memory cells comprises a vertical stack of a first electrode 151, an ovonic threshold switching material portion 152, and a second electrode 153. Each of the ovonic threshold switching material portions 152 in the two-dimensional array 100A of memory cells 180 has a respective shape of a frustum (e.g., inverted frustrum in this embodiment). In one embodiment, the memory device further comprises first electrically conductive lines 30 laterally extending along a first horizontal direction hd1. Each first electrode 151 in the two-dimensional array of memory cells contacts a respective portion of the first electrically conductive lines 30.

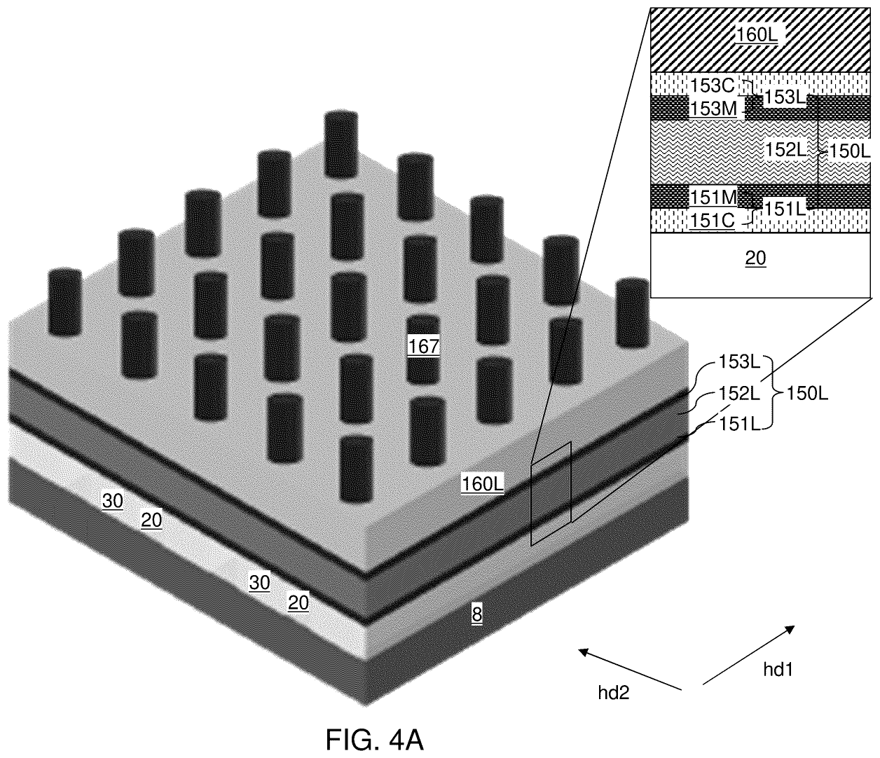

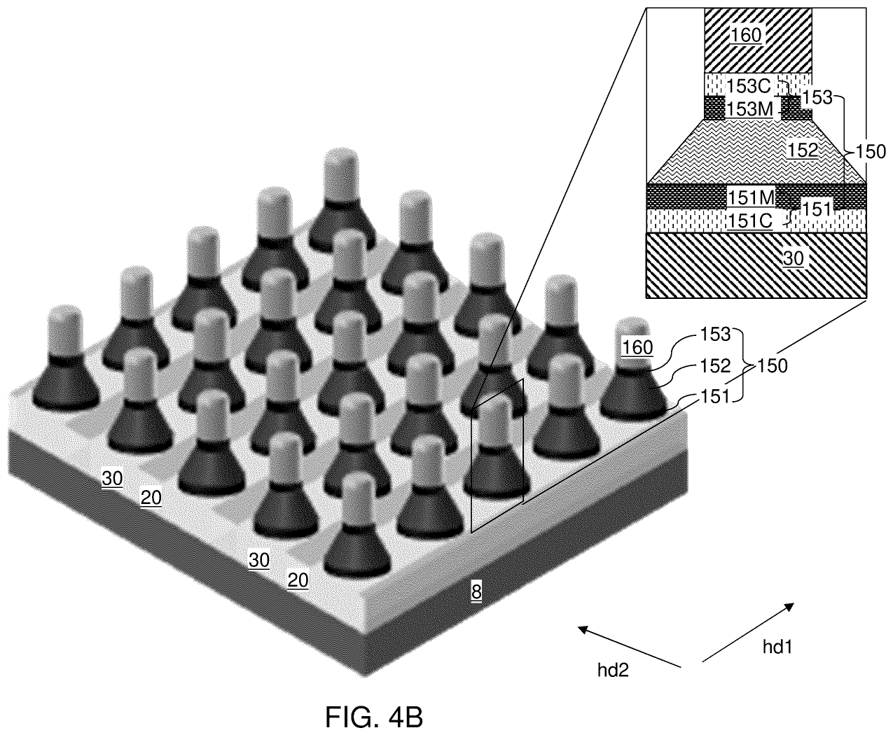

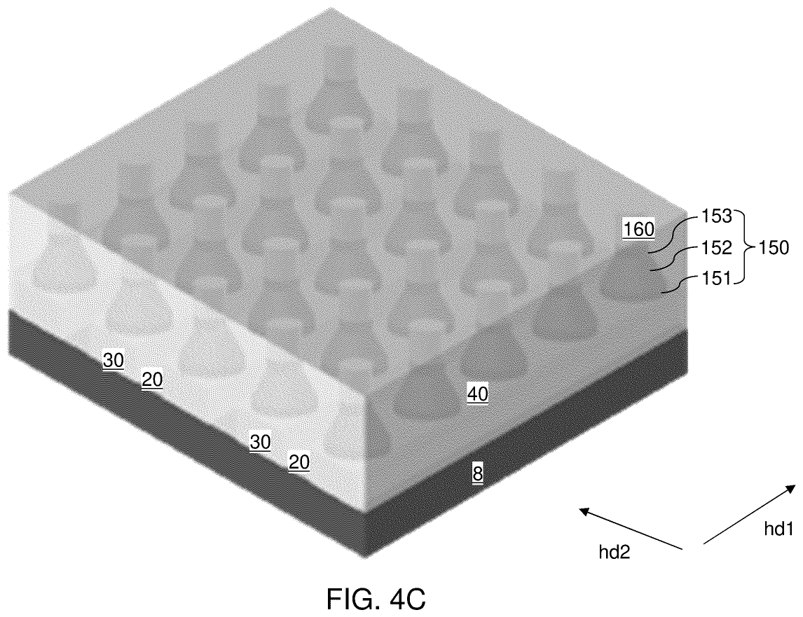

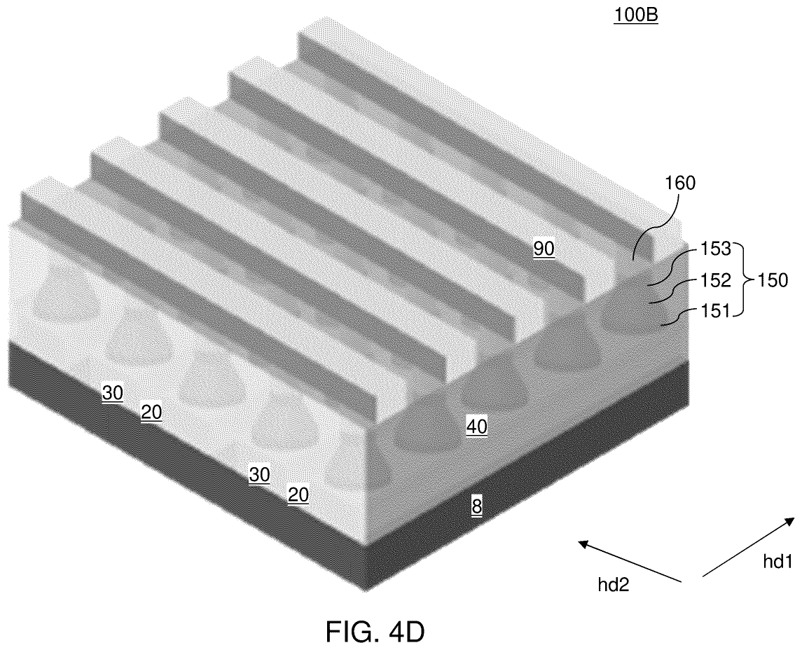

FIGS. 4A-4D are sequential perspective views of a second exemplary structure during formation of the two-dimensional array 100B of ovonic memory cells 180 of FIG. 2B according to the second embodiment of the present disclosure.

Referring to FIG. 4A, the second exemplary structure can be derived from the first exemplary structure illustrated in FIG. 3C by reducing the size of each discrete photoresist material portion 167 in the two-dimensional array of discrete photoresist material portions 167. In one embodiment, a maximum lateral dimension (such as a diameter) of each discrete photoresist material portion 167 may be in a range from 10 nm to 40 nm, although lesser and greater maximum lateral dimensions may also be employed.

Referring to FIG. 4B, an anisotropic etch process can be performed to transfer the pattern of the two-dimensional array of discrete photoresist material portions 167 through the metallic hard mask layer 160L. The metallic hard mask layer 160L can be patterned into a two-dimensional array of metallic pillar structures 160. In one embodiment, the metallic pillar structures 160 may have a circular cylindrical shape or an elliptical cylindrical shape.

The anisotropic etch process may be continued with a suitable change in the etch chemistry to etch unmasked portions of the second electrode material layer 153L. The second electrode material layer 153L is patterned into a two-dimensional array of second electrodes 153. Each second electrode 153 may comprise a layer stack of a second metallic material layer 153M and a second carbon-based electrode material layer 153C overlying the second metallic material layer 153M. The two-dimensional array of discrete photoresist material portions 167 can be subsequently removed, for example, by ashing.

The ovonic threshold switching material layer 152L can be patterned by transferring the pattern in the two-dimensional array of metallic pillar structures 160 through the ovonic threshold switching material layer 152L. In one embodiment, the pattern in the two-dimensional array of metallic pillar structures 160 can be transferred through the ovonic threshold switching material layer 152L by performing an ion beam etching process.

According to an aspect of the present disclosure, a single-step ion-beam etching (IBE) process may be employed to pattern the ovonic threshold switching material layer 152L into a two-dimensional array of ovonic threshold switching material portions 152 each having a shape of a respective conical frustum. In the single-step IBE process, a high energy ion beam impinges onto the ovonic threshold switching material layer 152L along a downward vertical direction or at a small tilt angle (which may be less than 35 degrees) relative to the downward vertical direction. In case the ion beam has a non-zero tilt angle, the direction of the ion beam may be gradually azimuthally rotated by 360 degrees around the vertical direction during the single-step IBE process. The single-step IBE process generates tapered sidewalls with a positive taper angle, i.e., an angle that causes a bottom region of each ovonic threshold switching material portion 152 to have a greater width than a top region of each ovonic threshold switching material portion 152.

In an alternative embodiment, the frustrum shaped ovonic threshold switching material portions 152 may be formed by a one-step reactive ion etching process which produces sidewall inhibitor deposition. In other words, the reactive ion etching process conditions are selected to form the ovonic threshold switching material portions 152 with tapered sidewalls, as shown in FIG. 4B.

Another anisotropic etch process may be performed to etch unmasked portions of the first electrode material layer 151L. The combination of the arrays of the metallic pillar structures 160, the second electrodes 153, and the ovonic threshold switching material portions 152 may be employed as an etch mask for patterning the first electrode material layer 151L. The first electrode material layer 151L is patterned into a two-dimensional array of first electrodes 151. Each first electrode 151 may comprise a layer stack of a first metallic material layer 151M and a first carbon-based electrode material layer 151C underlying the first metallic material layer 151M.

In the second embodiment, for each ovonic threshold switching material portion 152, a tapered surface of the ovonic threshold switching material portion 152 continuously extends from a top surface of the first electrode 151 to a bottom surface of the second electrode 153. The ovonic threshold switching material portion 152 has a variable horizontal cross-sectional area that decreases with a vertical distance from a horizontal plane including the top surfaces of the first electrodes 151. In one embodiment, the ovonic threshold switching material portions 152 have a respective circular or oval-shaped horizontal cross-sectional shape. Thus, in the second embodiment, each of the ovonic threshold switching material portions 152 in the two-dimensional array of memory cells has a respective shape of a right-side-up frustum.

Referring to FIG. 4C, at least one dielectric fill material, such as a combination of a silicon nitride liner and a silicon oxide fill material layer, can be deposited in the gaps among the arrays of the metallic pillar structures 160, the second electrodes 153, the ovonic threshold switching material portions 152, and the first electrodes 151. A suitable reflow process may optionally be performed to reduce, and/or eliminate, voids in the at least one dielectric fill material. A planarization process, such as a chemical mechanical polishing process, may be performed to remove portions of the at least one dielectric fill material from above the horizontal plane including the top surfaces of the metallic pillar structures 160. The remaining portion of the at least one dielectric fill material constitutes a dielectric fill material layer 40 that laterally surrounds the arrays of the metallic pillar structures 160, the second electrodes 153, the ovonic threshold switching material portions 152, and the first electrodes 151.

Referring to FIG. 4D, the second electrically conductive lines 90 can be formed on the physically exposed surfaces of the metallic pillar structures 160. Each second electrically conductive line 90 can laterally extend along the second horizontal direction hd2, and may contact a respective column of metallic pillar structures 160 that extends along the second horizontal direction hd2. The pitch of the second electrically conductive lines 90 along the first horizontal direction hd1 may be the same as the pitch of the two-dimensional array of metallic pillar structures 160 along the first horizontal direction hd1. An insulating material (not shown) can be deposited between neighboring pairs of second electrically conductive lines 90 to form second insulating rails (not shown). Alternatively, the second electrically conductive lines 90 may be formed by the above described damascene process. The second electrically conductive lines 90 laterally extend along the second horizontal direction hd2, and each second electrode 153 in the two-dimensional array of memory cells 180 contacts a respective one of the second electrically conductive lines 90.

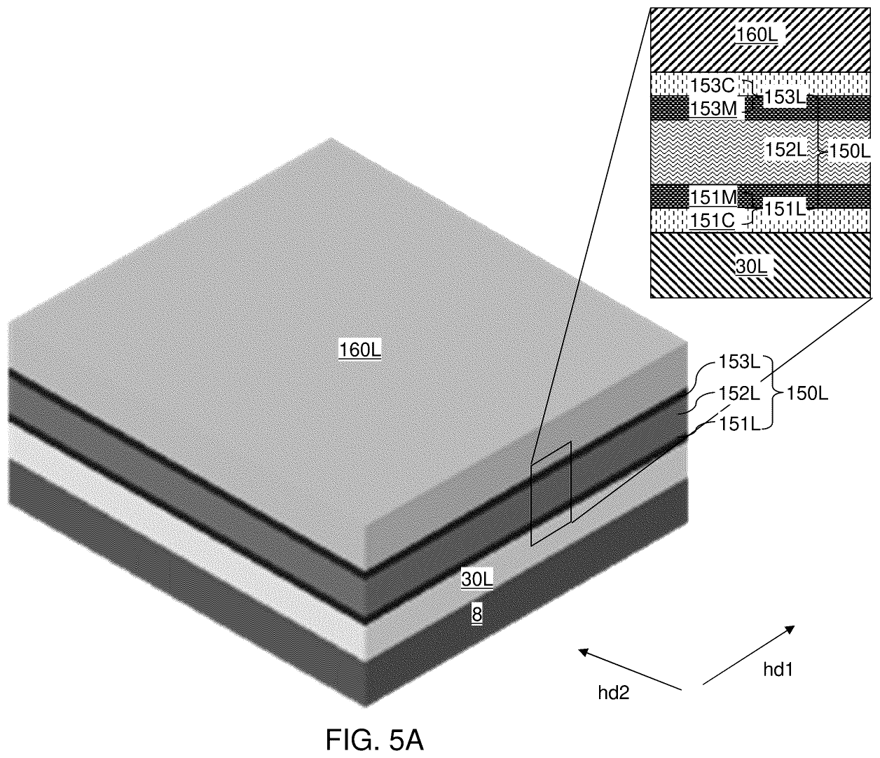

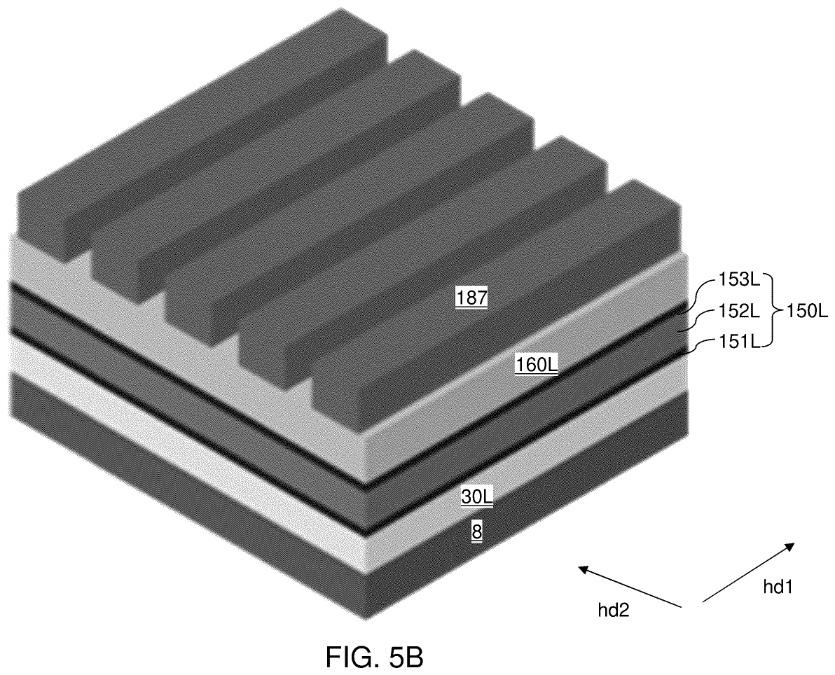

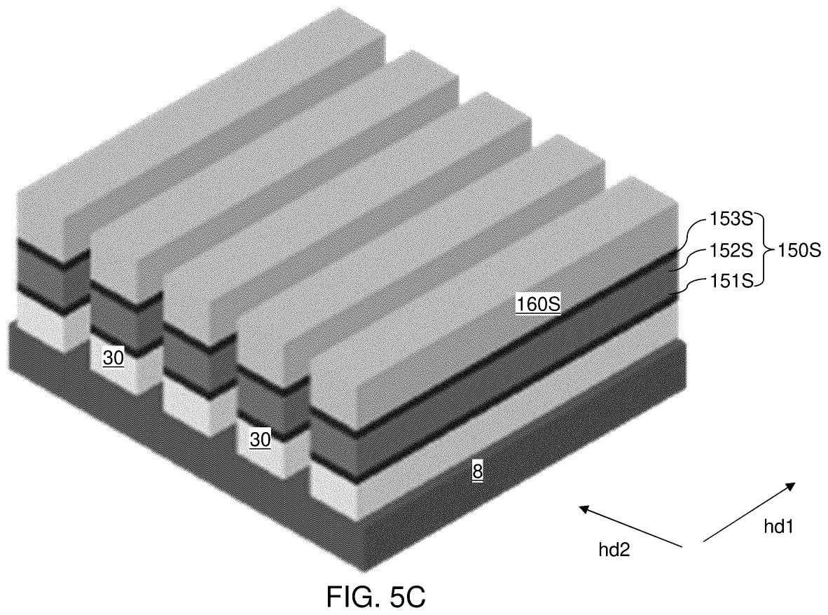

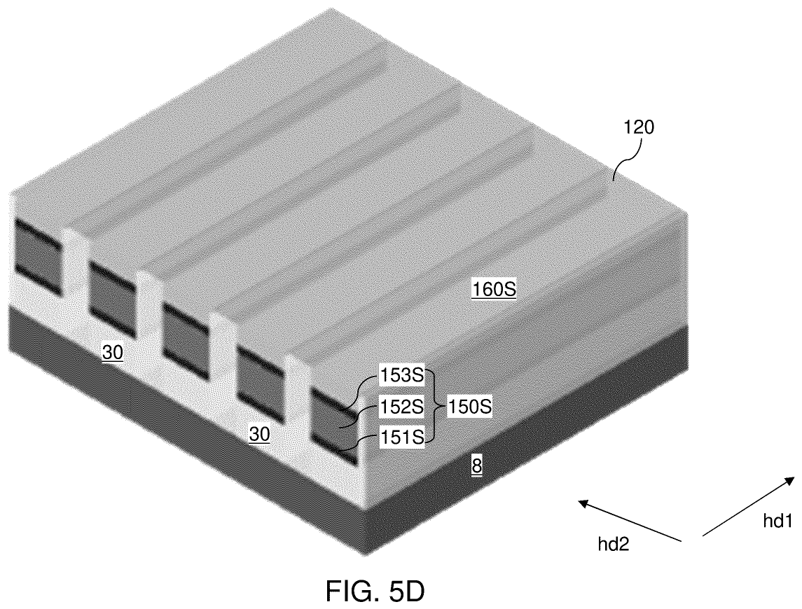

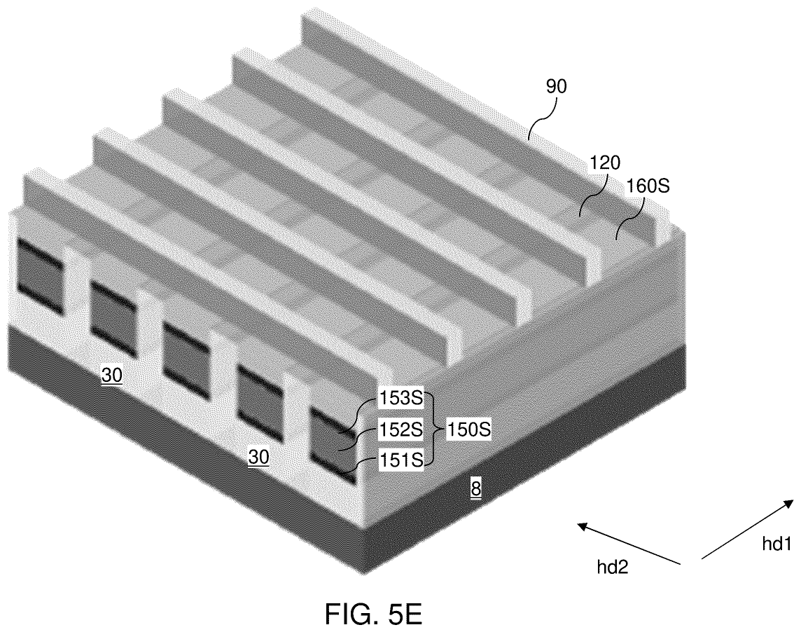

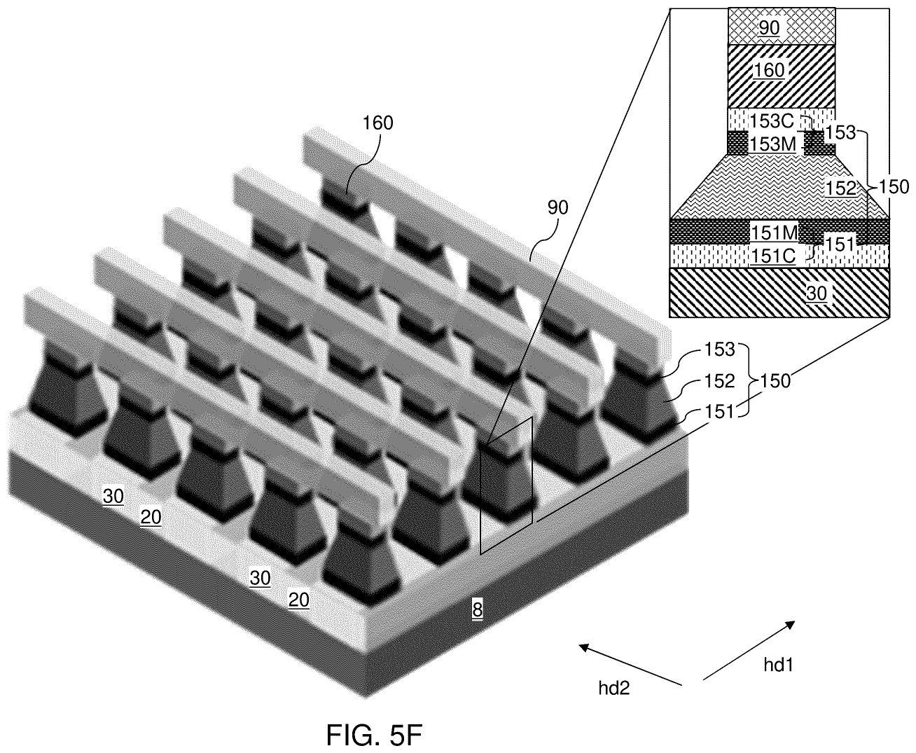

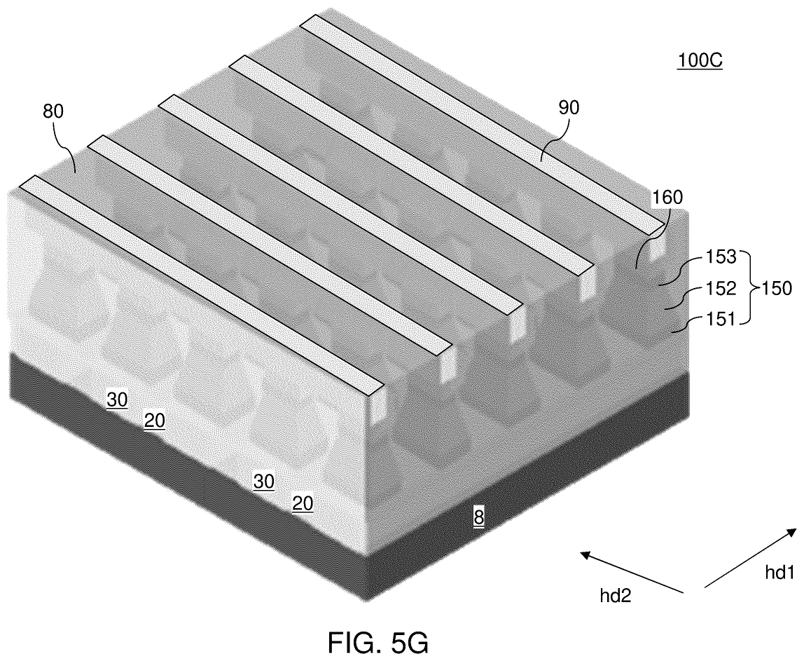

FIGS. 5A-5G are sequential perspective views of a third exemplary structure during formation of a two-dimensional array 100C of ovonic memory cells 180 according to the third embodiment of the present disclosure.

Referring to FIG. 5A, the third exemplary structure comprises a substrate 8 having an insulating top surface, a first electrically conductive layer 30L, an ovonic memory layer 150L, and a metallic hard mask layer 160L. The first electrically conductive layer 30L may have the same material composition and the same thickness as the first electrically conductive lines 30 discussed above. The first electrically conductive layer 30L may be deposited as a blanket layer, i.e., as an unpatterned material layer.

Referring to FIG. 5B, a photoresist layer can be applied over the metallic hard mask layer 160L, and can be lithographically patterned with a line-and-space pattern to form a one-dimensional array of photoresist rails 187. The one-dimensional array of photoresist rails 187 may have the same pattern as the pattern of the first electrically conductive lines 30 discussed above.

Referring to FIG. 5C, a first anisotropic etch process can be performed to transfer the pattern of the one-dimensional array of photoresist rails 187 through the metallic hard mask layer 160L. The metallic hard mask layer 160L can be patterned into a one-dimensional array of metallic strip structures 160S. The metallic strip structures 160S may have a same width throughout along the second horizontal direction hd2.

The first anisotropic etch process may be continued with a suitable change in the etch chemistry to etch unmasked portions of the second electrode material layer 153L. The second electrode material layer 153L is patterned into a one-dimensional array of second electrode strips 153S. Each second electrode strip 153S may comprise a layer stack of an optional second metallic material strip and a second carbon-based electrode material strip overlying the second metallic material layer strip. The one-dimensional array of photoresist rails 187 can be subsequently removed, for example, by ashing.

The ovonic threshold switching material layer 152L can be patterned by transferring the pattern in the one-dimensional array of metallic strip structures 160S through the ovonic threshold switching material layer 152L. In one embodiment, the pattern in the one-dimensional array of metallic strip structures 160S can be transferred through the ovonic threshold switching material layer 152L by performing an ion beam or a reactive ion etching process.

According to an aspect of the present disclosure, the ion beam etching process may comprise the two-step IBE process or a RIE process with undercutting described with reference to FIG. 3D, or a single-step IBE process or a RIE process described with reference to FIG. 4B. Patterned portions of the ovonic threshold switching material layer 152L comprise ovonic threshold switching material strips 152S. Accordingly, the vertical cross-sectional profile of each ovonic threshold switching material portion 152 along a vertical plane that is perpendicular to the first horizontal direction hd1 may have a shape of an inverted trapezoid having a greater lateral extent at top than at bottom, or may have a shape of an upright trapezoid having a lesser lateral extent at top than at bottom.

A second anisotropic etch process may be performed to etch unmasked portions of the first electrode material layer 151L. The combination of the arrays of the metallic strip structures 160S, the second electrode strips 153S, and the ovonic threshold switching material strips 152S may be employed as an etch mask for patterning the first electrode material layer 151L. The first electrode material layer 151L is patterned into a one-dimensional array of first electrode strips 151S. Each first electrode strip 151S may comprise a layer stack of an optional first metallic material strip and a first carbon-based electrode material strip underlying the second metallic material strip. Each contiguous combination of a first electrode strips 151S, an ovonic threshold switching material strip 152S, and a second electrode strip 153S constitutes an ovonic memory strip 150S.

The second anisotropic etch process may be continued with a change in the etch chemistry to etch unmasked portions of the first electrically conductive layer 30L. The first electrically conductive layer 30L may be patterned into a one-dimensional array of first electrically conductive lines 30.

Referring to FIG. 5D, a dielectric fill material may be deposited in the gaps between vertical stacks of a first electrically conductive line 30, a first electrode strip 151S, an ovonic threshold switching material strip 152S, a second electrode strip 153S, and a metallic strip structure 160S. The dielectric fill material may comprise, for example, a combination of a silicon nitride liner and a silicon oxide fill material. Portions of the dielectric fill material that overlies the horizontal plane including the top surfaces of the metallic strip structures 160S can be removed by performing a planarization process such as a chemical mechanical polishing (CMP) process. The remaining portions of the dielectric fill material comprise a first dielectric fill material layer 120 including a plurality of dielectric fill material rails that are laterally spaced apart along the second horizontal direction hd2.

Referring to FIG. 5E, second electrically conductive lines 90 can be formed on the physically exposed surfaces of the metallic pillar structures 160. Each second electrically conductive line 90 can laterally extend along the second horizontal direction hd2. The pitch of the second electrically conductive lines 90 along the first horizontal direction hd1 may be the same as the pitch of a two-dimensional array of metallic pillar structures 160 to be subsequently formed along the first horizontal direction hd1.

Referring to FIG. 5F, an anisotropic etch process can be performed to anisotropically etch portions of the first dielectric fill material layer 120, the metallic strip structures 160S, and the second electrode strips 153S employing the second electrically conductive lines 90 as an etch mask structure. The one-dimensional array of metallic strip structures 160S is patterned into a two-dimensional array of metallic pillar structures 160 having a respective rectangular horizontal cross-sectional shape. The one-dimensional array of second electrode strips 153S is patterned into a two-dimensional array of second electrodes 153 having a respective rectangular horizontal cross-sectional shape.

An ion beam etch process can be performed to pattern the one-dimensional array of ovonic threshold switching material strips 152S into a two-dimensional array of ovonic threshold switching material portions 152. According to an aspect of the present disclosure, the ion beam etching process may comprise the two-step IBE process described with reference to FIG. 3D, or a single-step IBE process described with reference to FIG. 4B. If the ion beam etching process employed at the processing steps of FIG. 5C comprises a two-step IBE process, the ion beam etching process employed at the processing steps of FIG. 5F comprises another two-step IBE process. If the ion beam etching process is employed at the processing steps of FIG. 5C comprises a single-step IBE process, the ion beam etching process employed at the processing steps of FIG. 5F comprises another single-step IBE process. Alternatively, the etching process employed at the processing steps of FIG. 5C comprises an RIE process with an undercut, then the etching process employed at the processing steps of FIG. 5F comprises another RIE process with the undercut.

Patterned portions of the one-dimensional array of ovonic threshold switching material strips 152S comprise a two-dimensional array of ovonic threshold switching material portions 152. Accordingly, the vertical cross-sectional profile of each ovonic threshold switching material portion 152 along a vertical plane that is perpendicular to the first horizontal direction hd1 may have a shape of an inverted trapezoid, and the vertical cross-sectional profile of each ovonic threshold switching material portion 152 along a vertical plane that is perpendicular to the second horizontal direction hd2 may have a shape of an inverted trapezoid, which forms an inverted pyramidal frustrum. Alternatively, the vertical cross-sectional profile of each ovonic threshold switching material portion 152 along a vertical plane that is perpendicular to the first horizontal direction hd1 may have a shape of an upright trapezoid having a lesser lateral extent at top than at bottom, and the vertical cross-sectional profile of each ovonic threshold switching material portion 152 along a vertical plane that is perpendicular to the second horizontal direction hd2 may have a shape of an upright trapezoid having a lesser lateral extent at top than at bottom which forms a right-side-up pyramidal frustrum. Remaining portions of the first dielectric fill material layer 120 located between the first electrically conductive lines 30 comprise the first insulating rails 20. In the third embodiment, the ovonic threshold switching material portions 152 may have a rectangular horizontal cross-sectional shape that changes in size along the vertical direction.

Referring to FIG. 5G, at lest one insulating fill material can be deposited in the voids underlying the horizontal plane including the top surfaces of the second electrically conductive lines 90. The at least one insulating fill material may comprise a combination of a silicon nitride liner and a silicon oxide fill material layer. Excess portions of the at least one insulating fill material can be removed from above the horizontal plane including the top surfaces of the second electrically conductive lines 90 by a planarization process, which may comprise a chemical mechanical polishing (CMP) process. Remaining portions of the at least one insulating fill material constitute an insulating matrix layer 80, which comprises a plurality of insulating material rails that laterally extend along the second horizontal direction hd2 and laterally spaced apart along the first horizontal direction hd1.

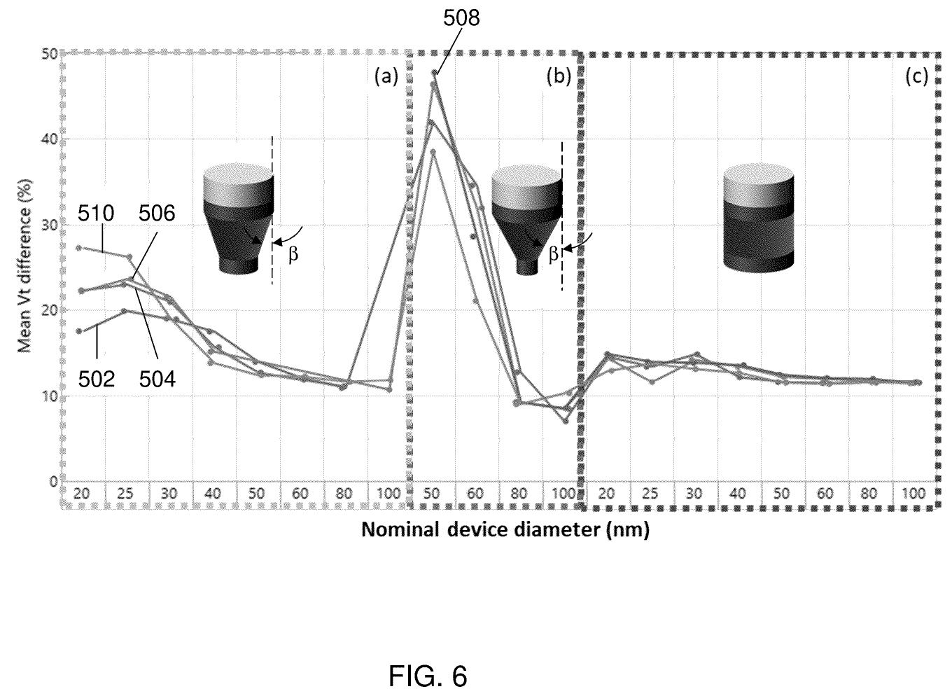

Referring to FIG. 6, data for DVth/Vth is illustrated for various shapes of ovonic threshold switching material portions 152. FIG. 6 is a plot of a mean threshold voltage difference (i.e., DVth/Vth) versus nominal portion 152 base diameter. In this embodiment, ΔVth is the difference between Vth+/− and Vth+/+, where Vth+/− is the threshold voltage going from a positive voltage pulse (previous pulse) to a negative voltage pulse (i.e., Vth measurement pulse), and Vth+/+ is the threshold voltage going from a positive voltage pulse to another positive voltage pulse. In this case, ΔVth/Vth={(Vth+/−)−(Vth+/+)}/(Vth+/+).

First-type ovonic memory cells 180 of the first embodiment are schematically illustrated in box (a), and the data for DVth/Vth for first-type ovonic memory cells 180 having various base dimensions (i.e., widest width of the ovonic threshold switching material portions 152) ranging from 20 nm to 100 nm are also shown in box (a). The first-type ovonic threshold switching material portions 152 may have a negative taper angle a of about 25 degrees.

Second-type ovonic memory cells 180 of the first embodiment are schematically illustrated in box (b), and the data for DVth/Vth second-type ovonic memory cells 180 having various base dimensions ranging from 50 nm to 100 nm are also shown in box (b). The second-type ovonic threshold switching material portions 152 may have a negative taper angle a of about 40 degrees.

Third-type ovonic memory cells of a comparative example are schematically illustrated in box (c), and the data for ΔVth/Vth for third-type ovonic memory cell having uniform lateral dimensions ranging from 20 nm to 100 nm are also shown in box (c).

The data plotted in FIG. 6 corresponds to hundreds of memory devices from three different wafers. The data in each box (a), (b) and (c) represents hundreds of memory devices on each wafer. For comparison, all data is plotted together. Lines 502 to 510 correspond to specific resistor lengths of resistors that are formed in electrical series with the memory devices. Line 502 corresponds to resistors having a predetermined length. Line 504 corresponds to a resistor having length that is 3.2/2 times the predetermined length of the resistor represented by line 502. Line 506 corresponds to a resistor having length that is two times the predetermined length of the resistor represented by line 502. Line 508 corresponds to a resistor having length that is 5/2 times the predetermined length of the resistor represented by line 502. Line 510 corresponds to a resistor having length that is four times the predetermined length of the resistor represented by line 502.

As shown in FIG. 6, the presence of a taper angle in an ovonic threshold switching material portion 152 can increase the value for DVth/Vth and thus increase the memory window for the memory cell 180. DVth/Vth values above 15%, such as 18 to 48% may be achieved. Enhancement in the value for DVth/Vth is more prominent when the lateral dimension of the neck portion of an ovonic threshold switching material portion 152 is not greater than 60 nm, such as 10 to 30 nm, for example 15 to 25 nm, e.g., about 20 nm, and the taper angle is increased above 30 degrees, such as 35 to 50 degrees. Without wishing to be bound by a particular theory, the neck width of about 10 to 30 nm is roughly comparable to a width of a filament that may be formed through the ovonic threshold switching material portion 152 during programming.

Referring to all drawings and according to various embodiments of the present disclosure, an ovonic memory element 150 includes a first electrode 151, a second electrode 153, and an ovonic threshold switching material portion 152 located between the first electrode and the second electrode. A first surface of the ovonic threshold switching material portion 152 facing the first electrode 151 is wider than an opposing second surface of the ovonic threshold switching material portion facing the second electrode 153.

In one embodiment, the first surface of the ovonic threshold switching material portion 152 contacts the first electrode 151, and the second surface of the ovonic threshold switching material portion 152 contacts the second electrode 153. In one embodiment, the first electrode 151 is located above the second electrode 153. In another embodiment, the first electrode 151 is located below the second electrode 153. In one embodiment, the ovonic threshold switching material portion comprises a chalcogenide material.

In one embodiment, the ovonic threshold switching material portion 152 has a shape of a frustrum (e.g., right-side-up or inverted frustrum). In one embodiment, tapered surface (e.g., sidewall) of the ovonic threshold switching material portion 152 continuously extends from the first electrode 151 to the second electrode 153. In one embodiment, the ovonic threshold switching material portion 152 has a variable horizontal cross-sectional area that decreases with a vertical distance from the second electrode 153 to the first electrode 151.

In the first and second embodiments, the ovonic threshold switching material portion 152 has a circular or oval-shaped horizontal cross-sectional shape. In the third embodiment, the ovonic threshold switching material portion 152 has a rectangular horizontal cross-sectional shape.

In one embodiment, the ovonic threshold switching material portion is configured to store data (i.e., the ovonic memory element 150 is the data storage element located in the OTS-only memory cell 180 which lacks a magnetic or phase change data storage element). In one embodiment, the ovonic memory element has a DVth/Vth value of greater than 15%.

In one embodiment, a memory device (e.g., memory cell 180), comprises the ovonic memory element 150, the first electrically conductive line 30 that laterally extends along a first horizontal direction hd1 and electrically connected to the first electrode 151, a second electrically conductive line 90 that laterally extends along a second horizontal direction hd2 and electrically connected to the second electrode 153, and a metallic pillar structure 160 located between the ovonic threshold switching material portion 152 and one of the first or the second electrically conductive lines (e.g., the second electrically conductive line 90).

In one embodiment, a method of operating the ovonic memory element 150 includes programming the ovonic threshold switching material portion 152 to store data by applying a programming voltage between the first electrode 151 and the second electrode 153; and reading the data stored in the ovonic threshold switching material portion 152 by applying a read voltage between the first electrode 151 and the second electrode 153, wherein the ovonic memory element 150 has a DVth/Vth value of greater than 15%.

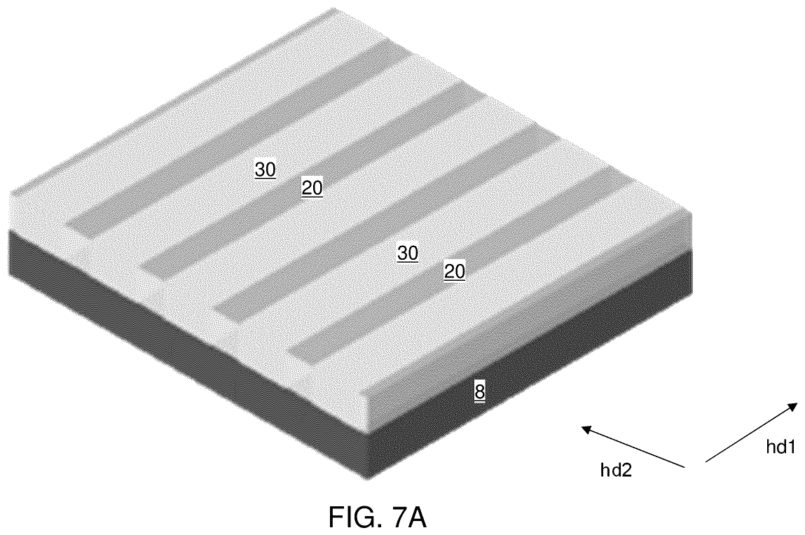

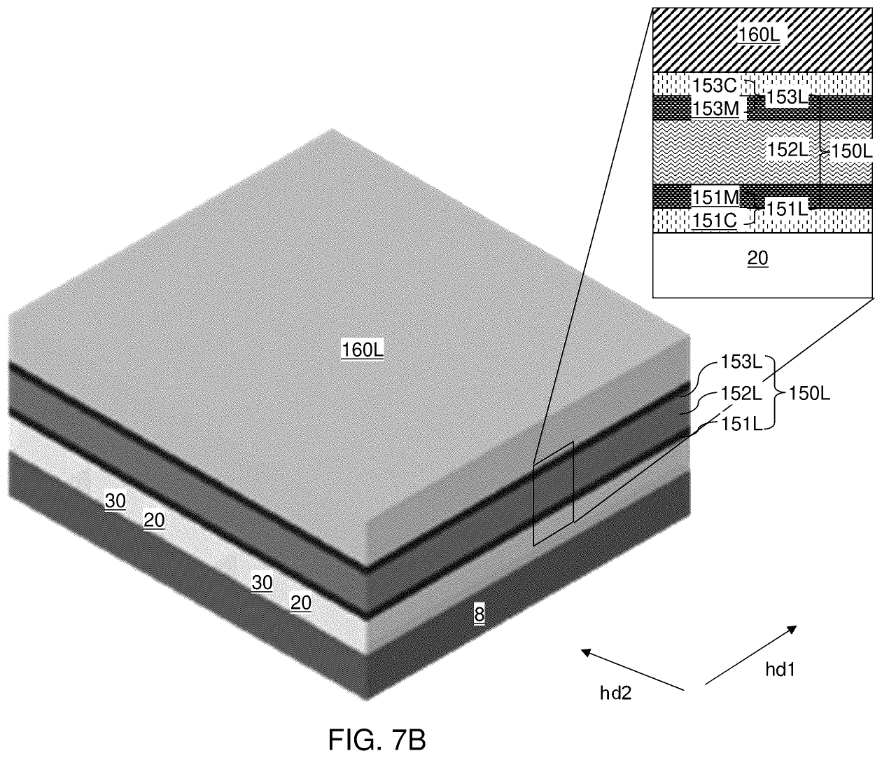

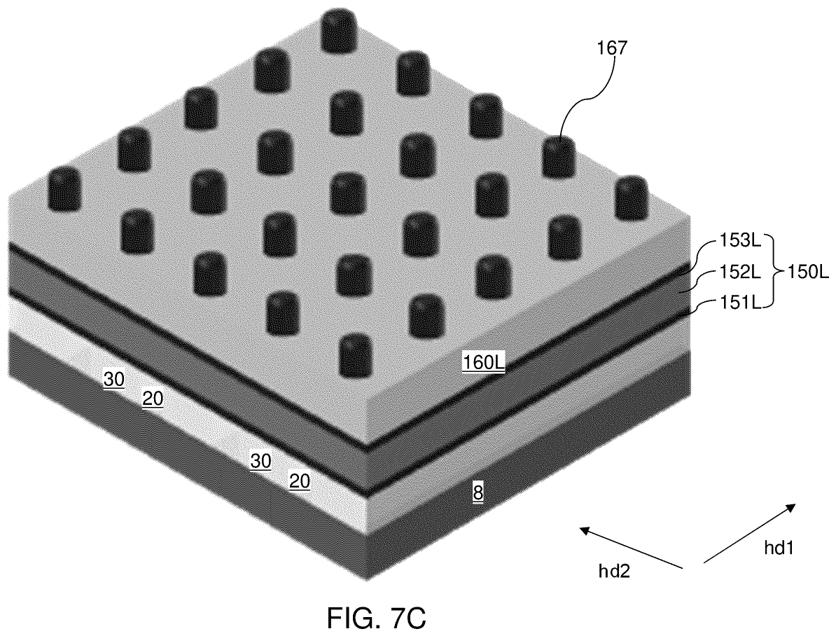

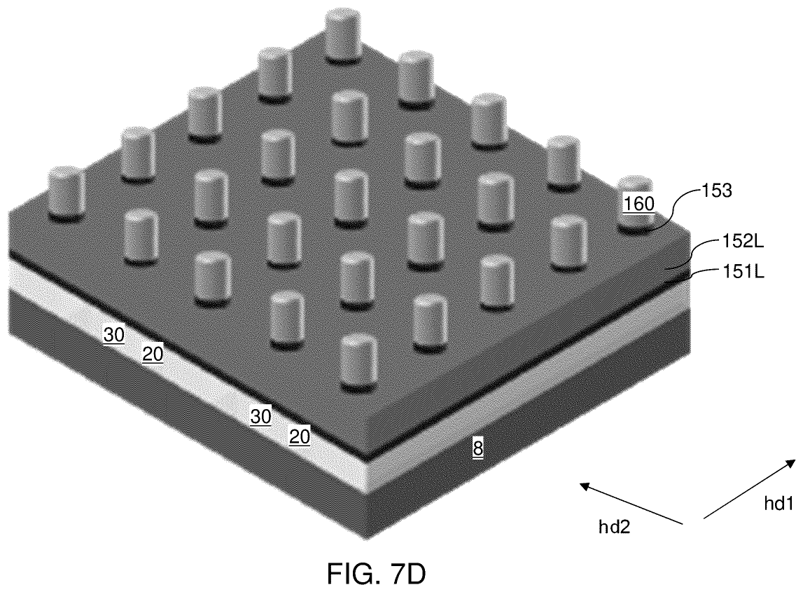

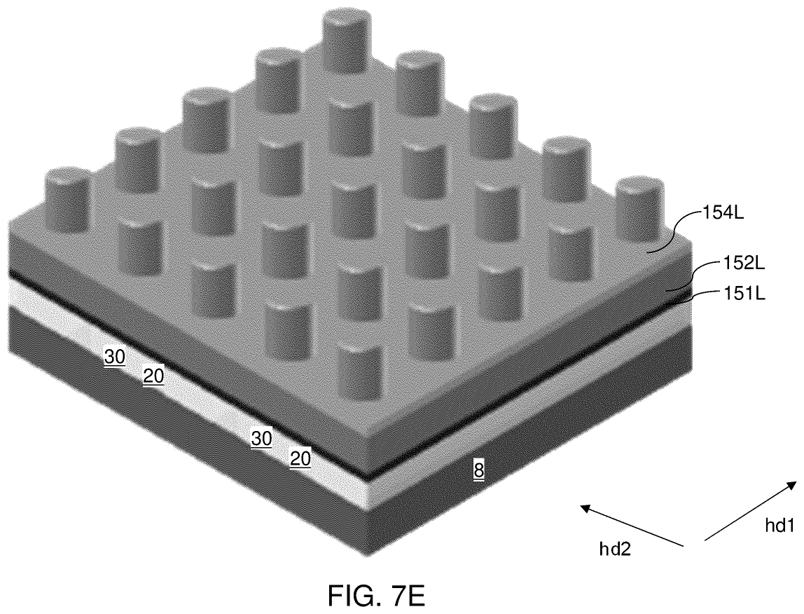

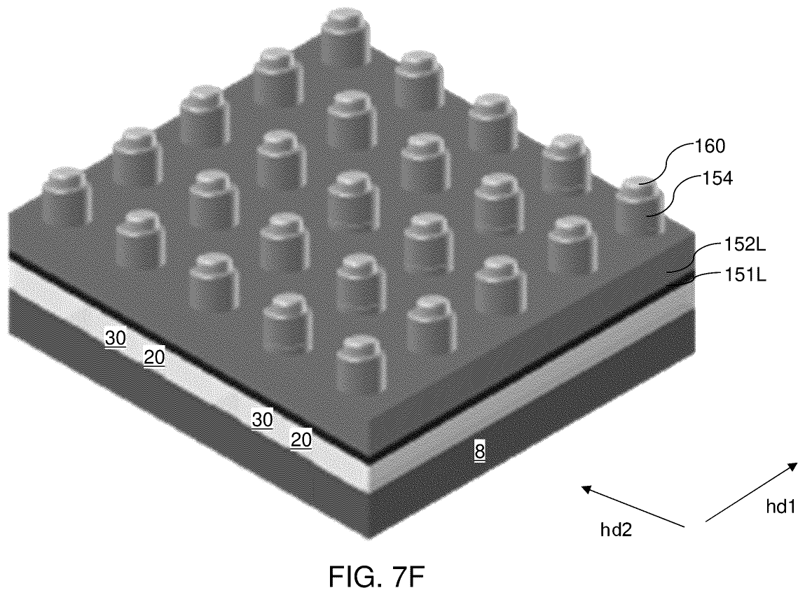

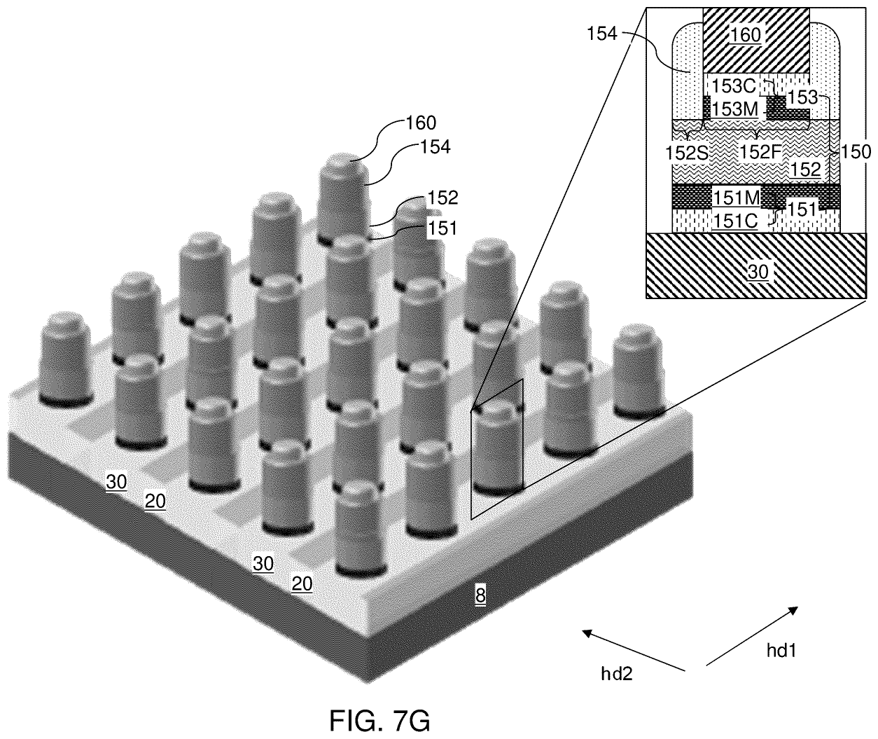

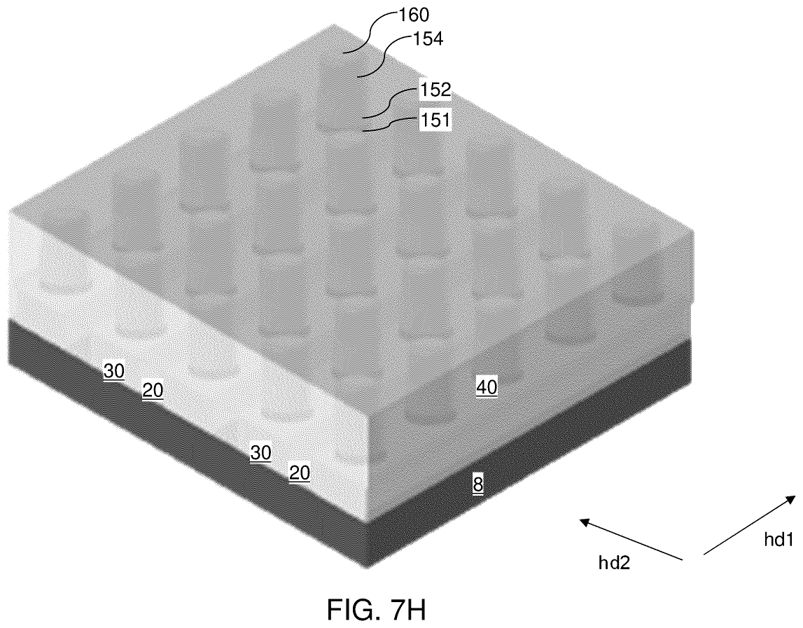

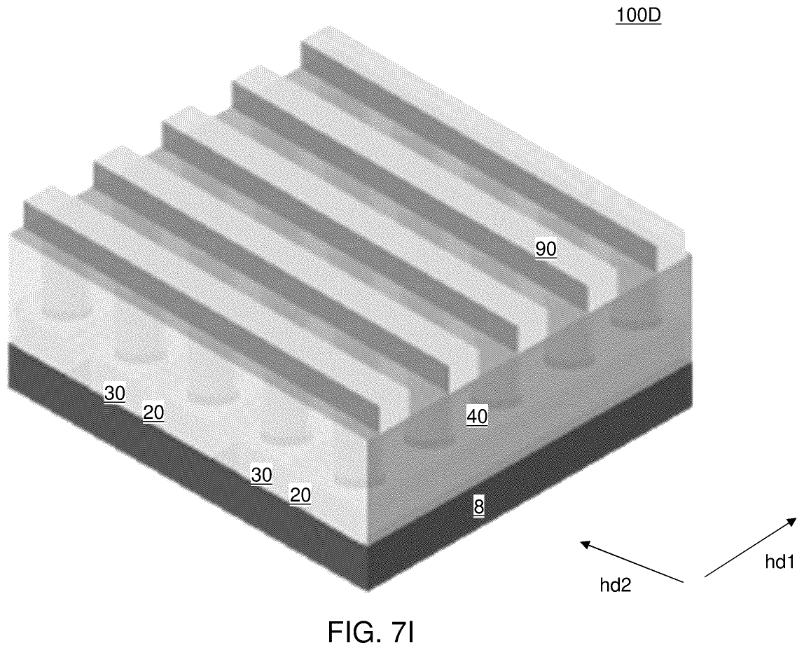

FIGS. 7A-7I are sequential perspective views of a fourth exemplary structure during formation of a two-dimensional array 100D of ovonic memory cells 180 according to a fourth embodiment of the present disclosure. Referring to FIG. 7A, the fourth exemplary structure according to the fourth embodiment of the present disclosure may be the same as the first exemplary structure described with reference to FIG. 3A.

Referring to FIG. 7B, the fourth exemplary structure according to the fourth embodiment of the present disclosure may be the same as the first exemplary structure described with reference to FIG. 3B.

Referring to FIG. 7C, a photoresist layer can be applied over the metallic hard mask layer 160L, and can be lithographically patterned to form a two-dimensional array of discrete photoresist material portions 167. The two-dimensional array of discrete photoresist material portions 167 may have a periodic pitch along the second horizontal direction hd2 that is the same as the pitch of the first electrically conductive lines 30 along the second horizontal direction hd2. In one embodiment, the two-dimensional array of discrete photoresist material portions 167 in the fourth exemplary structure may be derived from the two-dimensional array of discrete photoresist material portions 167 described with reference to FIG. 3C by reducing the lateral dimensions of each of the discrete photoresist material portions 167. In this case, the horizontal cross-sectional shape of each of the discrete photoresist material portions 167 may be about the same as the horizontal cross-sectional shape of a first electrode 151 in the first exemplary structure.

Referring to FIG. 7D, an anisotropic etch process can be performed to transfer the pattern of the two-dimensional array of discrete photoresist material portions 167 through the metallic hard mask layer 160L and the second electrode material layer 153L. The metallic hard mask layer 160L can be patterned into a two-dimensional array of metallic pillar structures 160. In one embodiment, the metallic pillar structures 160 may have a circular cylindrical shape or an elliptical cylindrical shape. The second electrode material layer 153L is patterned into a two-dimensional array of second electrodes 153. Each second electrode 153 may comprise a layer stack of a second metallic material layer 153M and a second carbon-based electrode material layer 153C overlying the second metallic material layer 153M. A terminal step of the anisotropic etch process that etches the second electrode material layer 153L may be selective to the ovonic threshold switching material layer 152L to prevent or minimize collateral etching of the material of the ovonic threshold switching material layer 152L. The two-dimensional array of discrete photoresist material portions 167 can be subsequently removed, for example, by ashing.

Referring to FIG. 7E, a dielectric spacer material layer 154L including a dielectric material can be conformally deposited over the physically exposed top surface of the ovonic threshold switching material layer 152L and on physically exposed surfaces of a two-dimensional array of metallic pillar structures 160 and on sidewalls of a two-dimensional array of second electrodes 153. The dielectric material of the dielectric spacer material layer 154L may comprise any dielectric material that does not react with the material of the ovonic threshold switching material layer 152L. Preferably but not necessarily, the dielectric material of the dielectric spacer material layer 154L may comprise a dielectric passivation material that can block diffusion of oxygen, hydrogen, moisture, and/or metallic impurities. For example, the dielectric passivation material of the dielectric spacer material layer 154L may comprise silicon nitride, silicon carbide nitride (i.e., silicon carbonitride), silicon oxynitride, etc. The dielectric spacer material layer 154L may be deposited by a conformal deposition process such as an atomic layer deposition (ALD) process. The thickness of the dielectric spacer material layer 154L may be in a range from 10% to 100% of the maximum lateral dimension of each second electrode 153, such that the dielectric spacer material layer 154L does not completely fill the entire spaces between the adjacent metallic pillar structures 160. In an illustrative example, the thickness of the dielectric spacer material layer 154L may be in a range from 2 nm to 40 nm, although lesser and greater thicknesses may also be employed.

Referring to FIG. 7F, an anisotropic etch process can be performed to remove horizontally-extending portions of the dielectric spacer material layer 154L. Each remaining tubular portion of the dielectric spacer material layer 154L constitutes a dielectric spacer 154. A two-dimensional array of dielectric spacers 154 may be formed. In a non-limiting illustrative example, each dielectric spacer 154 may have an inner cylindrical sidewall and an outer cylindrical sidewall. A top edge of the inner cylindrical sidewall of each dielectric spacer 154 may contact a cylindrical sidewall of a respective metallic pillar structure 160.

Referring to FIG. 7G, the ovonic threshold switching material layer 152L can be patterned by transferring the pattern in the combination of the two-dimensional array of metallic pillar structures 160 and the two-dimensional array of dielectric spacers 154 through the ovonic threshold switching material layer 152L. In one embodiment, the pattern in the combination of the two-dimensional array of metallic pillar structures 160 and the two-dimensional array of dielectric spacers 154 can be transferred through the ovonic threshold switching material layer 152L by performing an ion beam etching process. In one embodiment, an ion-beam etching (IBE) process may be employed to pattern the ovonic threshold switching material layer 152L into a two-dimensional array of ovonic threshold switching material portions 152 each having a shape of a respective cylinder.

The tilt angle of the ion beam(s) in the IBE process may be selected such that the sidewalls of the ovonic threshold switching material portions 152 are vertical, substantially vertical, and/or have a taper angle in a range from −5 degrees to +5 degrees. Generally, the area of the bottom surface of each ovonic threshold switching material portion 152 is greater than the area of the bottom surface of an overlying second electrode 153. In one embodiment, the area of the top surface of the ovonic threshold switching material portion 152 and the area of the bottom surface of the ovonic threshold switching material portion 152 may be the same for each ovonic threshold switching material portion 152, and the sidewalls of the ovonic threshold switching material portions 152 may be vertical. In this embodiment, the ovonic threshold switching material portions 152 have a circular or oval cylindrical shape instead of the frustum shape of the prior embodiments. However, in this embodiment, as in the prior embodiments, the two electrodes (151, 153) have a different size from each other. For example, one electrode (e.g., the first electrode 151) electrically contacting one end of the ovonic threshold switching material portion 152 has a larger area than the other electrode (e.g., the second electrode 153) which electrically contacts the opposite end of the same ovonic threshold switching material portion 152. Specifically, the first electrode 151 has a larger contact area that contacts one end of the ovonic threshold switching material portion 152 than the contact area of the second electrode 153 which contacts the other end of the ovonic threshold switching material portion 152.

Another anisotropic etch process may be performed to etch unmasked portions of the first electrode material layer 151L. The combination of the array of the metallic pillar structures 160 and the array of dielectric spacers 154 may be employed as an etch mask for patterning the first electrode material layer 151L. The first electrode material layer 151L is patterned into a two-dimensional array of first electrodes 151. Each first electrode 151 may comprise a layer stack of a first metallic material layer 151M and a first carbon-based electrode material layer 151C underlying the first metallic material layer 151M. Segments of top surfaces of the first electrically conductive lines 30 that are not covered by the first electrodes 151 can be physically exposed.

Referring to FIG. 7H, at least one dielectric fill material, such as a combination of a silicon nitride liner and a silicon oxide fill material layer, can be deposited in the gaps between the arrays of the dielectric spacers 154, the metallic pillar structures 160, the second electrodes 153, the ovonic threshold switching material portions 152, and the first electrodes 151. A suitable reflow process may optionally be performed to reduce and/or eliminate voids in the at least one dielectric fill material. A planarization process, such as a chemical mechanical polishing process, may be performed to remove portions of the at least one dielectric fill material from above the horizontal plane including the top surfaces of the metallic pillar structures 160. The remaining portion of the at least one dielectric fill material constitutes a dielectric fill material layer 40 that laterally surrounds the arrays of the dielectric spacers 154, the metallic pillar structures 160, the second electrodes 153, the ovonic threshold switching material portions 152, and the first electrodes 151.

Referring to FIG. 7I, the processing steps described with reference to FIG. 3F can be performed to form second electrically conductive lines 90. Each second electrically conductive line 90 can laterally extend along the second horizontal direction hd2, and may contact a respective column of metallic pillar structures 160 that extends along the second horizontal direction hd2. The pitch of the second electrically conductive lines 90 along the first horizontal direction hd1 may be the same as the pitch of the two-dimensional array of metallic pillar structures 160 along the first horizontal direction hd1.

In the fourth exemplary structure shown in the inset in FIG. 7G, each ovonic memory element 150 comprises a first electrode 151; a second electrode 153 vertically spaced from the first electrode 151; and an ovonic threshold switching material portion 152 located between the first electrode 151 and the second electrode 153. A top surface of the first electrode 151 that contacts a bottom surface of the ovonic threshold switching material portion 152 has a greater area than a bottom surface of the second electrode 153 that contacts a first segment 152F of a top surface of the ovonic threshold switching material portion 152. A dielectric spacer 154 contacts a sidewall of the second electrode 153 and a second segment of the top surface of the ovonic threshold switching material portion 152. An outer sidewall of the dielectric spacer 154 is vertically coincident with a sidewall of the ovonic threshold switching material portion 152 and with a sidewall of the first electrode 151. In one embodiment, the first segment 152F of a top surface of the ovonic threshold switching material portion 152 comprises a center segment of the top surface of the ovonic threshold switching material portion 152; the dielectric spacer 154 laterally surrounds the second electrode 153 and has a tubular configuration; and the second segment 152S of the top surface of the ovonic threshold switching material portion 152 comprises an annular surface having a uniform lateral spacing between an inner periphery and an outer periphery. The uniform lateral spacing is the lateral thickness of the dielectric spacer 154 (as measured between an inner cylindrical sidewall and an outer cylindrical sidewall).

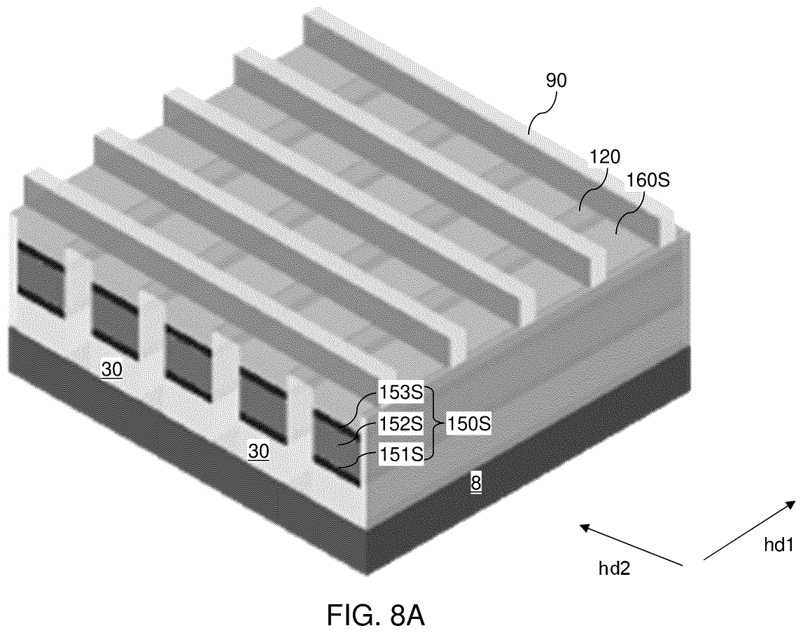

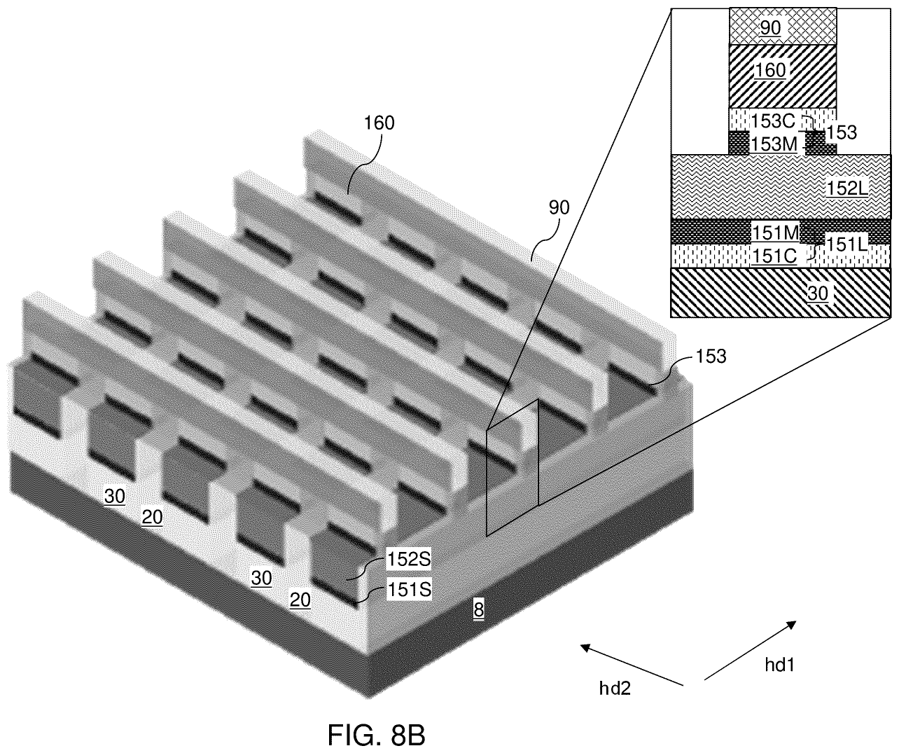

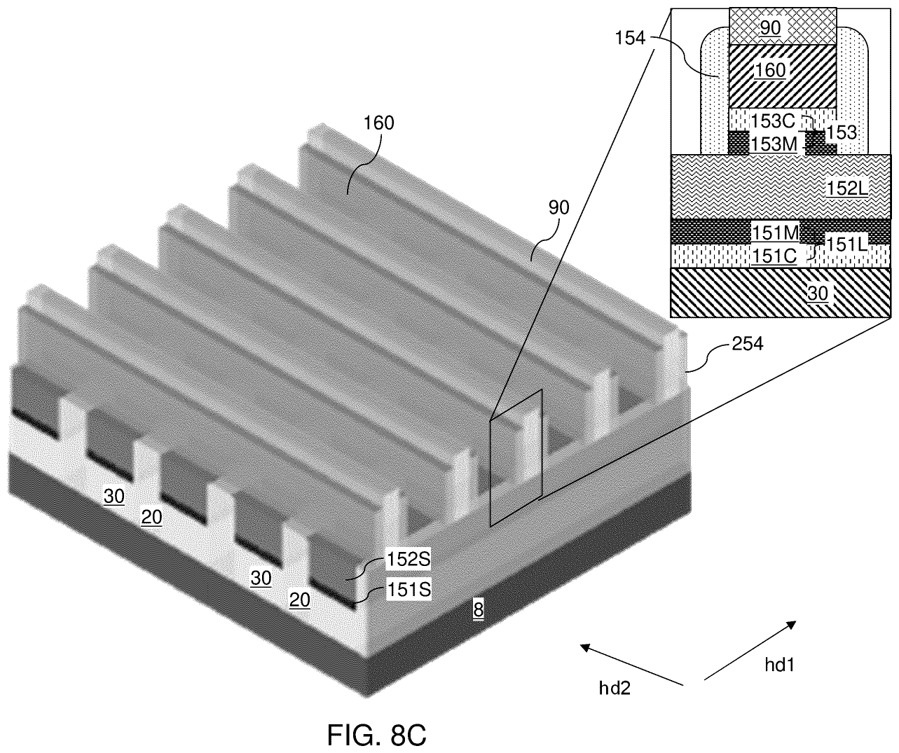

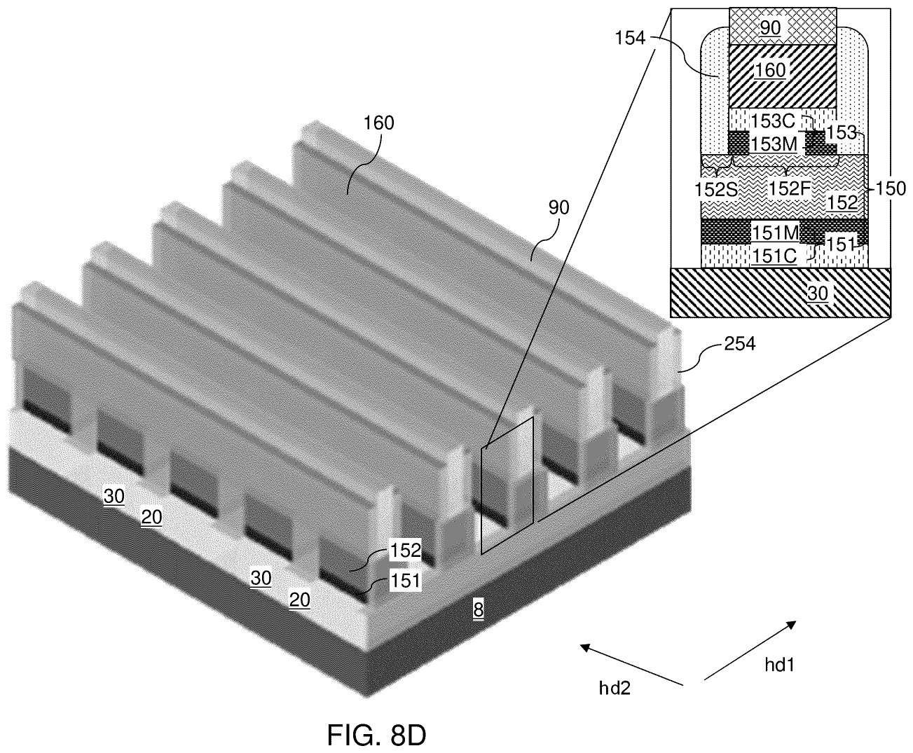

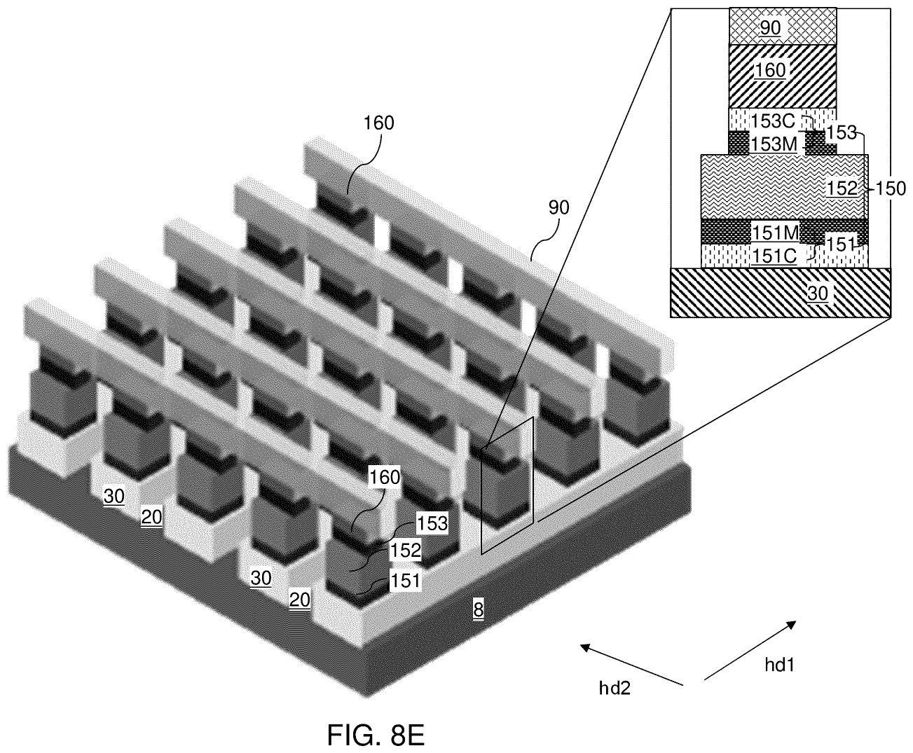

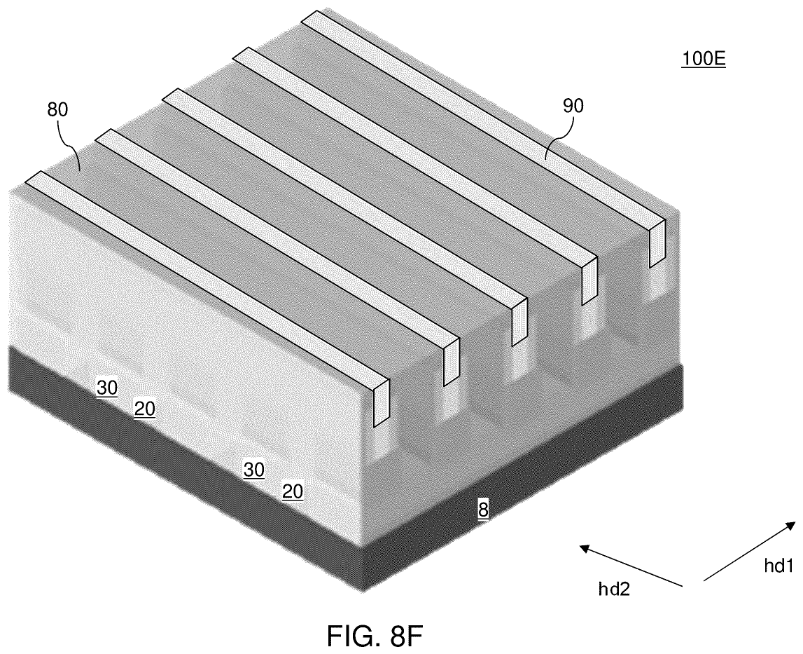

FIGS. 8A-8D and 8F are sequential perspective views of a fifth exemplary structure during formation of a two-dimensional array 100E of ovonic memory cells 180 according to a fifth embodiment of the present disclosure. FIG. 8E is a perspective view of the fifth exemplary structure after the processing steps of FIG. 8D in which dielectric spacers are omitted for illustrative purposes.

Referring to FIG. 8A, the fifth exemplary structure can be the same as the second exemplary structure described with reference to FIG. 5E.

Referring to FIG. 8B, an anisotropic etch process can be performed to anisotropically etch unmasked portions of the first dielectric fill material layer 120, the metallic strip structures 160S, and the second electrode strips 153S using the second electrically conductive lines 90 as an etch mask. The one-dimensional array of metallic strip structures 160S is patterned into a two-dimensional array of metallic pillar structures 160 having a respective rectangular horizontal cross-sectional shape. The one-dimensional array of second electrode strips 153S is patterned into a two-dimensional array of second electrodes 153 having a respective rectangular horizontal cross-sectional shape. The anisotropic etch process may etch the material of the first dielectric fill material layer 120 at approximately the same etch rate as the materials of the metallic strip structures 160S and the second electrode strips 153S.

Each second electrode 153 may comprise a layer stack of a second metallic material layer 153M and a second carbon-based electrode material layer 153C overlying the second metallic material layer 153M. A terminal step of the anisotropic etch process that etches the second electrode strips 153S may be selective to the material of the ovonic threshold switching material strips 152S to prevent and/or to minimize collateral etching of the material of the ovonic threshold switching material strips 152S.

Referring to FIG. 8C, a dielectric spacer material layer including is conformally deposited over the physically exposed top surface of the ovonic threshold switching material strips 152S and on physically exposed sidewalls of a two-dimensional array of metallic pillar structures 160 and of a two-dimensional array of second electrodes 153. The dielectric material of the dielectric spacer material layer may be the same as the dielectric material of the dielectric spacer material layer 154L described with reference to FIG. 7E. The dielectric spacer material layer may be deposited by a conformal deposition process, such as a atomic layer deposition (ALD) process. The thickness of the dielectric spacer material layer may be in a range from 10% to 100% of the maximum lateral dimension of each second electrode 153 along the first horizontal direction hd1. In an illustrative example, the thickness of the dielectric spacer material layer may be in a range from 2 nm to 40 nm, although lesser and greater thicknesses may also be employed.

An anisotropic etch process can be performed to remove horizontally-extending portions of the dielectric spacer material layer. Each remaining portion of the dielectric spacer material layer constitutes a dielectric spacer 154. A one-dimensional array of dielectric spacers 154 may be formed. In a non-limiting illustrative example, each dielectric spacer 154 may have planar vertical sidewalls that are perpendicular to the first horizontal direction hd1. In one embodiment, each dielectric spacer 154 may contact sidewalls of a respective one-dimensional array of metallic pillar structures 160, and may contact sidewalls of a respective one-dimensional array of second electrodes 153.

Referring to FIGS. 8D and 8E, the fifth exemplary structure is illustrated after performing after patterning the ovonic threshold switching material strips 152S and the first electrode strips 151S. FIG. 8D illustrates all components in the fifth exemplary structure, and FIG. 8E omits the dielectric spacers 154 for the purpose of illustration (although the dielectric spacers 154 are present after patterning the first electrode strips 151S).

In one embodiment, the pattern in the combination of the one-dimensional array of second electrically conductive lines 90 and the dielectric spacers 154 can be transferred through the ovonic threshold switching material strips 152S by performing an ion beam etching process. In one embodiment, an ion-beam etching (IBE) process may be employed to pattern the ovonic threshold switching material strips 152S into a two-dimensional array of ovonic threshold switching material portions 152 each having a shape of a respective rectangular parallelopiped, i.e., a respective cuboid. In one embodiment, each ovonic threshold switching material portion 152 may have a respective rectangular horizontal cross-sectional shape and a respective set of four planar sidewalls which may be vertical.

The tilt angle of the ion beam(s) in the IBE process may be selected such that the sidewalls of the ovonic threshold switching material portions 152 are vertical, substantially vertical and/or have a taper angle in a range from −5 degrees to +5 degrees. Generally, the area of the bottom surface of each ovonic threshold switching material portion 152 is greater than the area of the bottom surface of an overlying second electrode 153. In one embodiment, the area of the top surface of the ovonic threshold switching material portion 152 and the area of the bottom surface of the ovonic threshold switching material portion 152 may be the same for each ovonic threshold switching material portion 152, and the sidewalls of the ovonic threshold switching material portions 152 may be vertical. Another anisotropic etch process may be performed to etch unmasked portions of the first electrode strips 151S. The combination of the one-dimensional array of second electrically conductive lines 90 and the dielectric spacers 154 may be employed as an etch mask for patterning the first electrode strips 151S. The first electrode strips 151S are patterned into a two-dimensional array of first electrodes 151. Each first electrode 151 may comprise a layer stack of a first metallic material layer 151M and a first carbon-based electrode material layer 151C underlying the first metallic material layer 151M. Segments of top surfaces of the first electrically conductive lines 30 that are not covered by the first electrodes 151 can be physically exposed.

Referring to FIG. 8F, at least one dielectric fill material, such as a combination of a silicon nitride liner and a silicon oxide fill material layer, can be deposited in the gaps between neighboring pairs of the dielectric spacers 154 and between neighboring pairs of the second electrically conductive lines 90. A suitable reflow process may optionally be performed to reduce and/or eliminate voids in the at least one dielectric fill material. A planarization process, such as a chemical mechanical polishing process, may be performed to remove portions of the at least one dielectric fill material from above the horizontal plane including the top surfaces of the second electrically conductive lines 90. The remaining portions of the at least one dielectric fill material an insulating matrix layer 80.

In the fifth exemplary structure shown in the inset in FIG. 8D, each ovonic memory element 150 comprises a first electrode 151; a second electrode 153 vertically spaced from the first electrode 151; and an ovonic threshold switching material portion 152 located between the first electrode 151 and the second electrode 153. A top surface of the first electrode 151 that contacts a bottom surface of the ovonic threshold switching material portion 152 has a greater lateral dimension along a first horizontal direction hd1 and a greater area than a bottom surface of the second electrode 153 that contacts a first segment 152F of a top surface of the ovonic threshold switching material portion 152. A dielectric spacer 154 contacts a sidewall of the second electrode 153 and a second segment 152S of the top surface of the ovonic threshold switching material portion 152. An outer sidewall of the dielectric spacer 154 is vertically coincident with a sidewall of the ovonic threshold switching material portion 152 and with a sidewall of the first electrode 151.

The first electrode 151 and the second electrode 153 within each ovonic memory element 150 may have a same lateral extent along the second horizontal direction hd2. In one embodiment, an additional ovonic memory element 150 may be laterally spaced from the ovonic memory element 150 along a second horizontal direction hd2, and may comprise an additional first electrode 151, an additional second electrode 153, and an additional ovonic threshold switching material portion 152 located between the additional first electrode and the additional second electrode 153. The dielectric spacer 154 contacts a sidewall of the additional second electrode 153 and a segment of a top surface of the additional ovonic threshold switching material portion 152. In one embodiment, each dielectric spacer 154 may contact and laterally surround a row of metallic pillar structures 160 and a row of second electrodes 153. Each dielectric spacer 154 may contact a pair of rectangular top surface segments of each ovonic threshold switching material portion 152 within a respective row of ovonic threshold switching material portions 152 that are arranged along the second horizontal direction hd2.

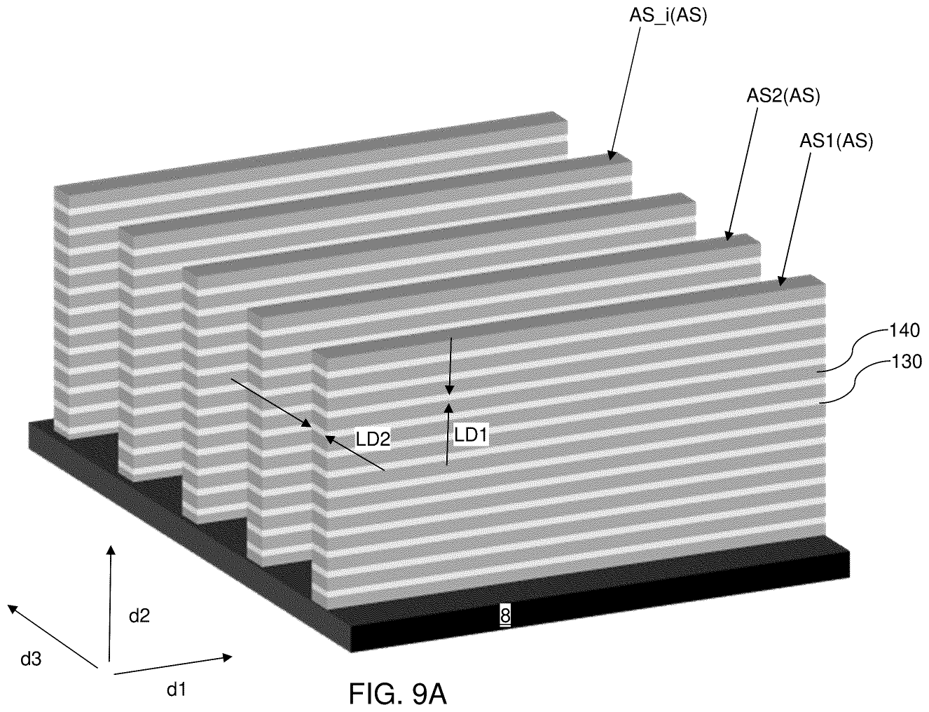

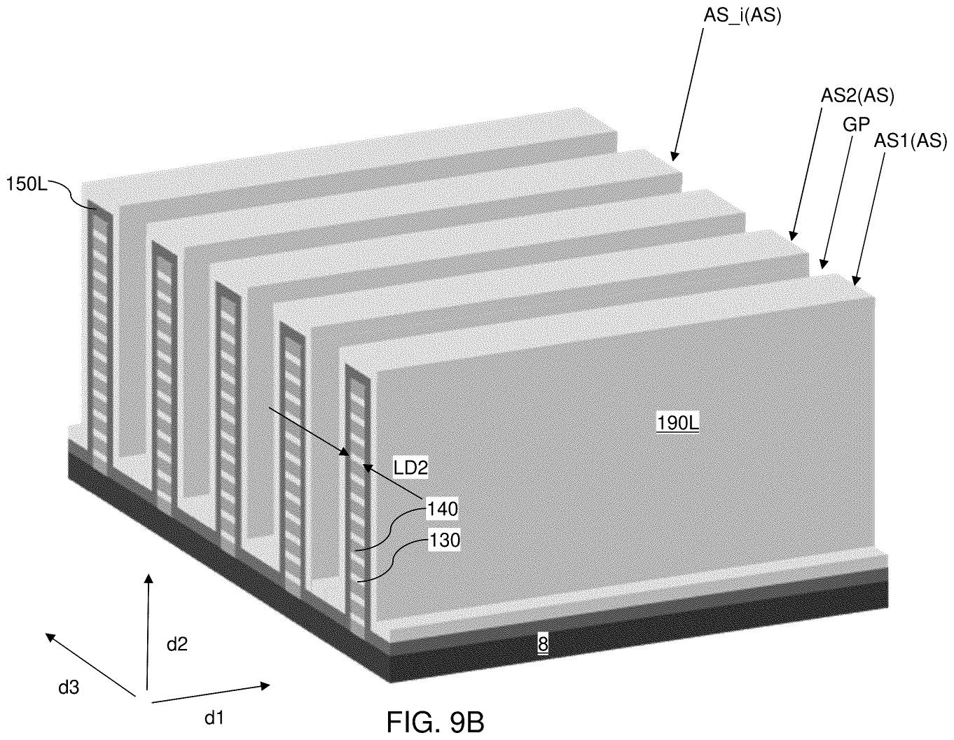

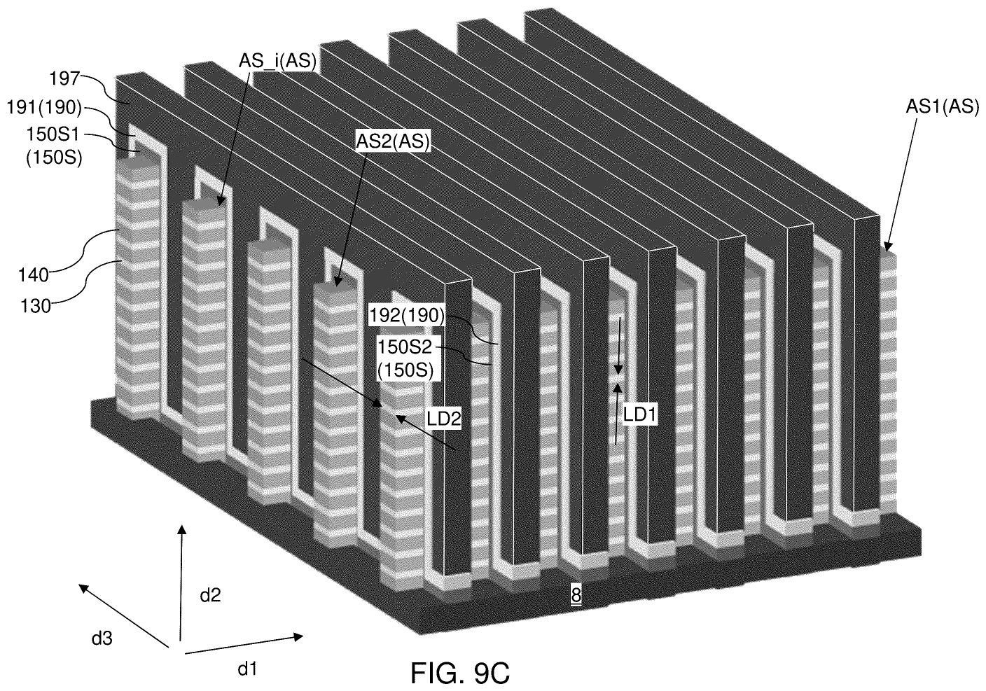

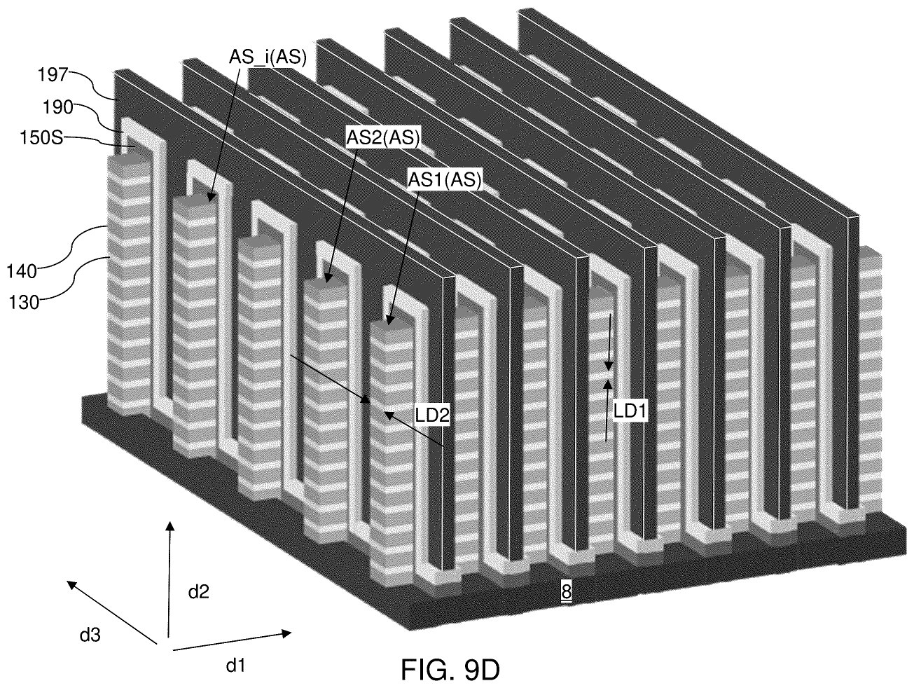

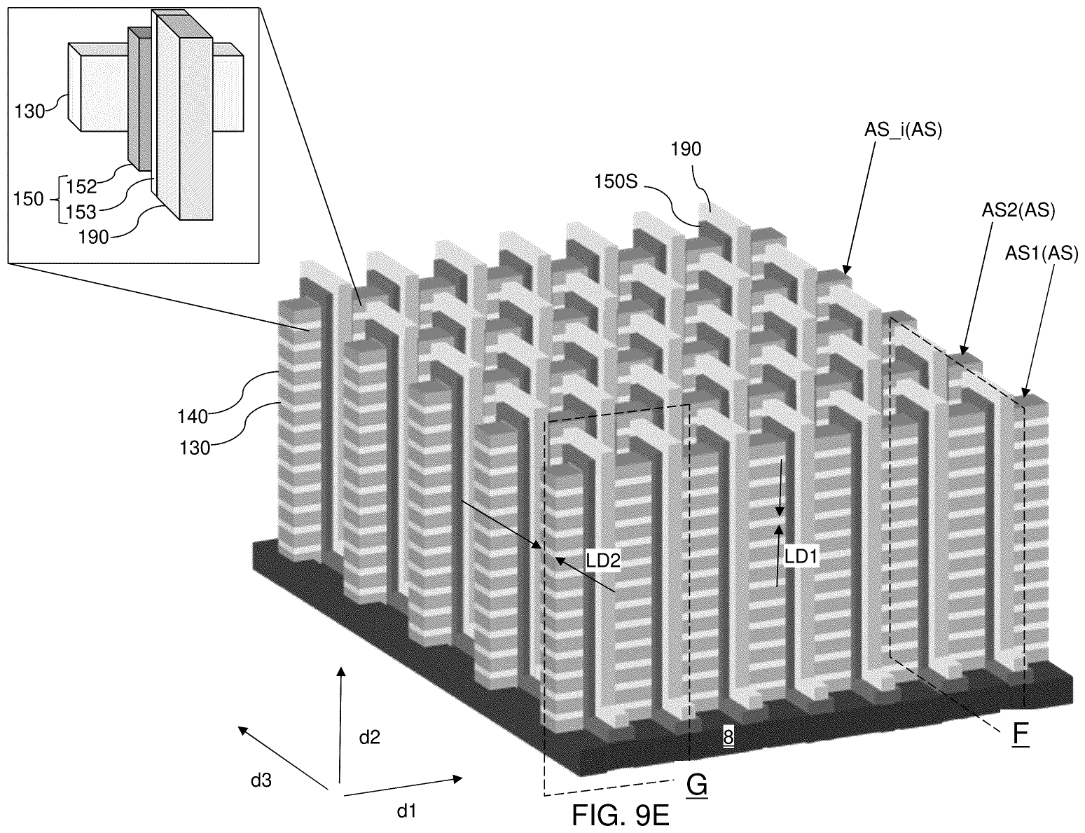

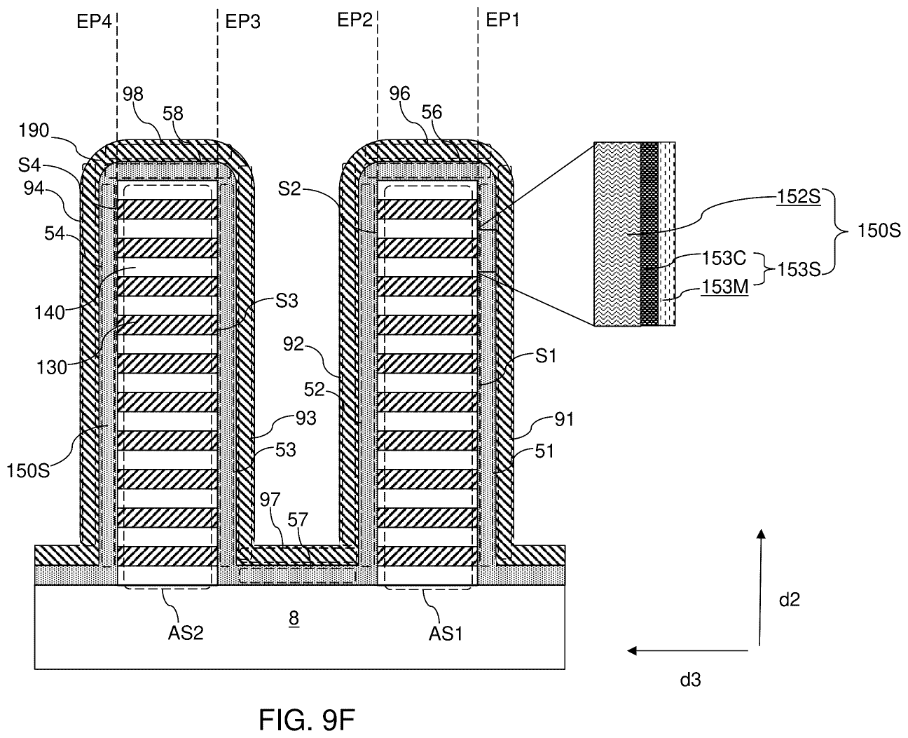

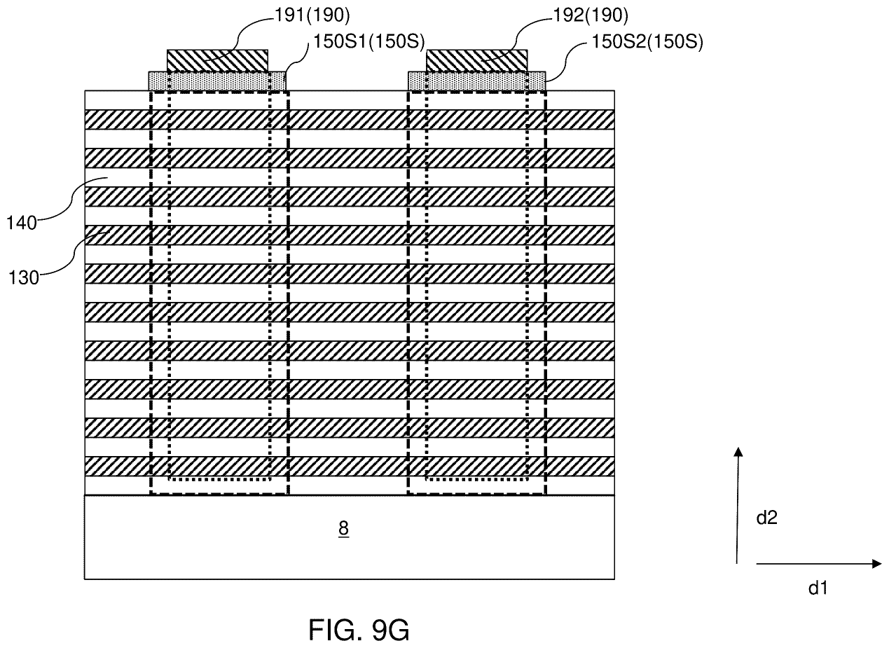

FIGS. 9A-9E are sequential perspective views of a sixth exemplary structure during formation of a three-dimensional array of ovonic memory cells according to a sixth embodiment of the present disclosure.

Referring to FIG. 9A, a vertically alternating sequence of blanket (unpatterned) insulating layers and blanket electrically conductive layers can be formed over a planar top surface of a substrate 8. In one embodiment, the substrate 8 may laterally extend along a first direction d1 (such as a first horizontal direction), and may have a planar top surface (i.e., a top surface that is located within a Euclidean plane) that is perpendicular to a second direction d2 (such as a vertical direction). The planar top surface of the substrate 8 may laterally extend along a third direction d3 that is perpendicular to the first direction d1 and to the second direction d2. In one embodiment, the planar top surface of the substrate 8 may be an insulating surface. In one embodiment, the substrate 8 may comprise a semiconductor substrate with an insulating material layer (such as a silicon oxide layer) on top. In this case, the planar top surface of the substrate may be a horizontal surface of the insulating material layer.

Each blanket insulating layer comprises and/or consists essentially of an insulating material such as silicon oxide, and may have a thickness in a range from 20 nm to 100 nm, although lesser and greater thicknesses may also be employed. Each blanket electrically conductive layer comprises and/or consists essentially of an electrically conductive material such as a refractory metal (such as W, Mo, Ta, etc.) and/or a conductive metallic nitride material (such as TiN, WN, TaN, MON, etc.), and may have a thickness in a range from 20 nm to 100 nm, although lesser and greater thicknesses may also be employed. Each neighboring pair of a blanket insulating layer and a blanket electrically conductive layer constitutes a repetition unit, which is repeated along the second direction d2 (which may be a vertical direction) with a periodicity. The total number of repetitions of the repletion unit in the vertically alternating sequence may be in a range from 2 to 2¹⁰, such as from 8 to 2⁸, although a greater number of repetitions may also be employed. A bottommost layer and a topmost layer within the vertically alternating sequence may be blanket insulating layers.

A photoresist layer (not shown) may be applied over the vertically alternating sequence, and may be lithographically patterned into a periodic line and space pattern that laterally extends along the first direction d1 (which may be a first horizontal direction) and is repeated with a periodicity along the third direction d3 (which may be a second horizontal direction). The width of each patterned line-shaped portion of the photoresist layer along the third direction d3 may be in a range from 20 nm to 200 nm, such as from 40 nm to 100 nm, although lesser and greater widths may also be employed. The spacing between each neighboring pair of patterned line-shaped portions of the photoresist layer along the third direction d3 may be in a range from 30 nm to 300 nm, such as from 60 nm to 150 nm, although lesser and greater spacings may also be employed.

An anisotropic etch process can be performed to transfer the pattern in the photoresist layer through the vertically alternating sequence of blanket insulating layers and blanket electrically conductive layers. The topmost layer within the substrate 8 may function as an etch stop material layer for the anisotropic etch process. Each patterned portion of the vertically alternating sequence may comprise a wall-shaped structure that laterally extends along the first direction d1 and has a uniform width along the third direction d3. Each patterned portion of the blanket insulating layers comprises an insulating rail 140 that extends along the first direction d1 with a uniform cross-sectional shape along cut planes that are perpendicular to the first direction d1. Each patterned portion of the blanket electrically conductive layers comprises an electrically conductive rail 130 that extends along the first direction d1 with a uniform cross-sectional shape along cut planes that are perpendicular to the first direction d1.

Each contiguous set of remaining portions of the vertically alternating sequence constitutes an alternating stack AS. The alternating stacks AS may be sequentially numbered from one side to another, for example, along the third direction d3 with positive integers beginning with 1. For example, the alternating stacks AS may comprise a first alternating stack AS1, a second alternating stack AS2, etc. An i-th alternating stack AS_i is the i-th alternating stack as counted from the side including the first alternating stack AS1. The alternating stacks AS may be repeated with a periodicity along the third direction d3. Each alternating stack AS may comprise a respective pair of planar surfaces (i.e., surfaces that are contained within a respective Euclidean plane) that are perpendicular to the third direction d3. For example, the first alternating stack AS1 may comprise a first surface and a second surface that are perpendicular to the third direction d3, the second alternating stack AS2 may comprise a third surface and a fourth surface that are perpendicular to the third direction d3, and the i-th alternating stack AS_i may comprise a (2i-1)-th surface and a (2i)-th surface that are perpendicular to the third direction d3.

Each electrically conductive rail 130 extends along the first direct d1, has a first uniform lateral dimension LD1 (such as a height) along the second direction d2, and has a second uniform lateral dimension LD2 (such as a width) along the third direction d3. Generally, each alternating stack AS may have a shape of a rectangular parallelopiped. In one embodiment, each of the lateral extent of each alternating stack AS along the first direction d1 and the lateral extent of each alternating stack AS along the second direction d2 may be greater than the lateral extent of each alternating stack AS along the third direction d3. In this case, the vertical surfaces of each alternating stack AS that are perpendicular to the third direction d3 may be major surfaces of the respective alternating stack AS. As used herein, a “major surface” of an element refers to a surface having a surface area that is at least ⅙ of the total surface area of the element.

Generally, a first alternating stack AS1 of first insulating rails 140 and first electrically conductive rails 130 can be formed over a substrate 8. The first insulating rails 140 and first electrically conductive rails 130 extend along a first direction d1, and are interlaced along a second direction d2 such that the first insulating rails 140 and the first electrically conductive rails 130 alternate along the second (e.g., vertical) direction d2. The first alternating stack AS1 comprises a first surface and a second surface that are spaced from each other along a third direction d3 that is perpendicular to the first direction d1 and the second direction d2.

Referring to FIG. 9B, the ovonic memory layer 150L can be formed over the alternating stacks AS. The ovonic memory layer 150L may comprise a layer stack of an ovonic threshold switching material layer 152L and an optional second electrode material layer 153L. In this embodiment, the first electrode material layer 151L is omitted to avoid short circuiting the electrically conductive rails 130. Each component layer within the ovonic memory layer 150L may be deposited by a respective conformal deposition process, and thus, may have a respective uniform thickness throughout. For example, atomic layer deposition may be employed to deposit at least one of the component layers in the ovonic memory layer 150L.

Subsequently, a conductive material layer 190L may be conformally deposited over the ovonic memory layer 150L. The conductive material layer 190L comprises an electrically conductive material such as a refractory metal (such as W, Mo, Ta, etc.) or a conductive metallic nitride material (such as TIN, WN, TaN, MON, etc.), and may have a thickness in a range from 20 nm to 100 nm, although lesser and greater thicknesses may also be employed. The conductive material layer 190L may be deposited by a conformal deposition process, such as a atomic layer deposition (ALD) process. The thickness of the ovonic memory layer 150L and the thickness of the conductive material layer 190L may be selected such that an unfilled gap GP laterally extending along the first direction d1 is present between each neighboring pair of alternating stacks AS.

Referring to FIG. 9C, a photoresist layer 197 can be applied over the conductive material layer 190L and in the gaps GP, and can be lithographically patterned into a line-and-space pattern that laterally extends along the third direction d3 and laterally spaced apart along the first direction d1. In one embodiment, the line-and-space pattern may be a periodic pattern.

The width of each patterned line-shaped portion of the photoresist layer 197 along the first direction d1 may be in a range from 30 nm to 300 nm, such as from 60 nm to 150 nm, although lesser and greater widths may also be employed. The spacing between each neighboring pair of patterned line-shaped portions of the photoresist layer 197 along the first direction d1 may be in a range from 30 nm to 300 nm, such as from 60 nm to 150 nm, although lesser and greater spacings may also be employed.

An anisotropic etch process can be performed to sequentially etch materials of the conductive material layer 190L and the ovonic memory layer 150L selective to the materials of the alternating stacks AS. The anisotropic etch process may comprise a sequence of selective anisotropic etch steps such that the various materials of the conductive material layer 190L and the ovonic memory layer 150L are sequentially etched from top to bottom and/or from outside to inside preferably with selectivity to an immediately underlying material. The terminal step of the anisotropic etch process may etch the material(s) of the first electrode material layer 152L (within the ovonic memory layer 150L) selective to the materials of the alternating stacks AS and the topmost layer of the substrate 8.

Remaining portions of the ovonic memory layer 150L comprise ovonic memory strips 150S. Each ovonic memory strip 150S continuously extends generally along the third direction d3 with directional undulations along the second direction d2. A plurality of ovonic memory strips 150S can be formed such that the ovonic memory strips 150S are arranged along the first direction d1 and are laterally spaced apart along the first direction d1, and extend along the third direction d3. The plurality of ovonic memory strips 150S may be sequentially numbered with positive integers beginning with 1 along the first direction d1. For example, the ovonic memory strips 150S may comprise a first ovonic memory strip 150S1, a second ovonic memory strip 150S2, etc.

Remaining portions of the conductive material layer 190L comprise conductive lines 190. Each conductive line 190 continuously extends generally along the third direction d3 with directional undulations along the second direction d2. Each conductive line 190 may have the same lateral dimension along the first direction d1 (which may be a first horizontal direction) as a respective underlying ovonic memory strip 150S. A plurality of conductive lines 190 can be formed such that the conductive lines 190 are arranged along the first direction d1 and are laterally spaced apart along the first direction d1, and extend along the third direction d3. The plurality of conductive lines 190 may be sequentially numbered with positive integers beginning with 1 along the first direction d1. For example, the conductive lines 190 may comprise a first conductive line 191, a second conductive line 192, etc.

In summary, a one-dimensional array of ovonic memory strip 150S can be formed over a one-dimensional array of alternating stack AS. Each ovonic memory strip 150S has a comb shape comprising vertical tooth portions connected to each other by a top horizontal connecting portion. Each vertical tooth portion comprises one of a plurality of ovonic memory strip segments extending along the second direction d2 and in contact with a surface of a respective alternating stack AS that is perpendicular to the third direction d3. A one-dimensional array of conductive lines 190 can be formed over the one-dimensional array of ovonic memory strips 150S. Each conductive line 190 has a comb shape comprising vertical tooth portions connected to each other by a top horizontal connecting portion. Each tooth portion comprises one of a plurality of conductive line segments extending along the second direction hd2 and in contact with a respective one of the ovonic memory strip segments.

Referring to FIG. 9D, the photoresist layer 197 may be isotropically trimmed by a trimming distance that is less than one half of the lateral dimension of each patterned portion of the photoresist layer 197 along the first direction d1. In one embodiment, the width of each trimmed line-shaped portion of the photoresist layer 197 along the first direction d1 may be in a range from 20 nm to 200 nm, such as from 40 nm to 100 nm, although lesser and greater widths may also be employed.

Referring to FIGS. 9E, 9F, and 9G, the sixth exemplary structure is illustrated after performing an anisotropic trimming etch process. As shown in the insets in FIGS. 9E and 9G, each ovonic memory strip 150S comprises a plurality of ovonic memory elements 150 located at the levels of the second electrically conductive rails 130. Each of the ovonic memory elements 150 comprises an ovonic threshold switching material portion 152 and the second electrode 153. An inner surface of the second electrode 153 contacts an outer surface of the ovonic threshold switching material portion 152.

The anisotropic trimming etch process etches unmasked portions of the conductive lines 190 and the second electrodes 153 selective to the materials of the ovonic threshold switching material portion 152, the alternating stacks AS, and the topmost layer of the substrate 8. Portions of the conductive lines 190 and the second electrode 153 that are not covered by the trimmed line-and-space pattern of the photoresist layer 197 can be removed by the anisotropic etch process. Thus, the conductive lines 190 and the second electrodes 153 can be trimmed along the first direction d1. The photoresist layer 197 can be subsequently removed, for example, by ashing.

Suitable electrical contacts can be made to each of the electrically conductive rails 130, for example, by patterning stepped surfaces in each of the alternating stacks AS in a contact region (not illustrated), and by forming conductive via structures on each of the electrically conductive rails 130. The contact region may be laterally spaced from the illustrated region of the sixth exemplary structure in FIG. 9E along the first direction d1. Further, additional contact via structures can be formed on each of the conductive lines 190. A set of electrically conductive rails 130 and a set of conductive lines 190 may be formed. One set of the set of electrically conductive rails 130 and the set of conductive lines 190 may be employed as first electrically conductive lines 30 in a RAM device 500 illustrated in FIG. 1. Another set of the set of electrically conductive rails 130 and the set of conductive lines 190 may be employed as second electrically conductive lines 90 in a RAM device 500 illustrated in FIG. 1.

In summary, a plurality of alternating stacks AS can be formed over a substrate 8. Each alternating stack AS comprises a respective set of insulating rails 140 and a respective set of electrically conductive rails 130 that are interlaced along the second (e.g., vertical) direction d2. Each alternating stack AS may comprise a respective pair of major surfaces. For example, as shown in FIG. 9F, a first alternating stack AS1 may comprise a first surface S1 contained within a first Euclidean plane EP1, and a second surface S2 contained within a second Euclidean plane EP2; a second alternating stack AS2 may comprise a third surface S3 contained within a third Euclidean plane EP3, and a fourth surface S4 contained within a fourth Euclidean plane EP4; etc.

As shown in FIG. 9F, each comb shaped ovonic memory strip 150S may comprise a first ovonic memory strip segment (e.g., first tooth) 51 extending along the second direction d2 and in contact with the first surface S1 of the first alternating stack AS1, a second ovonic memory strip segment (e.g., second tooth) 52 extending along the second direction d2 and in contact with the second surface S2 of the first alternating stack AS1, a third ovonic memory strip segment (e.g., third tooth) 53 extending along the second direction d2 and in contact with the third surface S3 of the second alternating stack AS2, a fourth ovonic memory strip segment (e.g., fourth tooth) 54 extending along the second direction d2 and in contact with the fourth surface S4 of the second alternating stack AS2, etc. Further, each ovonic memory strip 150S may comprise a first distal connecting ovonic memory strip segment (e.g., first horizontal connecting portion) 56 extending along the third direction d3 and in contact with a minor surface (such as a top surface) of the first alternating stack AS1; a second distal connecting ovonic memory strip segment (e.g., second horizontal connecting portion) 58 extending along the third direction d3 and in contact with a minor surface (such as a top surface) of the second alternating stack AS2; etc. Yet further, each ovonic memory strip 150S may comprise proximal connecting ovonic memory strip segment 57 extending along the third direction d3 and in contact with a planar surface of the substrate 8, such as the top surface of the substrate 8.

Each conductive line 190 may comprise a first conductive line segment 91 extending along the second direction d2 and in contact with a first ovonic memory strip segment 51; a second conductive line segment 92 extending along the second direction d2 and in contact with a second ovonic memory strip segment 52; a third conductive line segment 93 extending along the second direction d2 and in contact with a third ovonic memory strip segment 53; a fourth conductive line segment 94 extending along the second direction d2 and in contact with a fourth ovonic memory strip segment 54; etc. Further, each conductive line 190 may comprise a first distal connecting conductive line segment 96 extending along the third direction d3 over the first alternating stack AS1 and in contact with a first distal connecting ovonic memory strip segment 56; a second distal connecting conductive line segment 98 extending along the third direction d3 over the second alternating stack AS2 and in contact with a second distal connecting ovonic memory strip segment 58; etc. Yet further, each conductive line 190 may comprise proximal connecting conductive line segments 97 extending along the third direction d3, overlying the planar surface of the substrate 8, and contacting a respective one of the proximal connecting ovonic memory strip segments 57.

A plurality of ovonic memory strips 150S may be arranged along the first direction d1 as a one-dimensional periodic array of ovonic memory strips 150S. The ovonic memory strips 150S within the one-dimensional periodic array of ovonic memory strips 150S may be sequentially numbered individually with positive integers beginning with 1. For example, the ovonic memory strips 150S may comprise a first ovonic memory strip 150S1, a second ovonic memory strip 150S2, etc.

A plurality of conductive lines 190 may be arranged along the first direction d1 as a one-dimensional periodic array of conductive lines 190. The conductive lines 190 within the one-dimensional periodic array of conductive lines 190 may be sequentially numbered individually with positive integers beginning with 1. For example, the o conductive lines 190 may comprise a first conductive line 191, a second conductive line 192, etc.

Referring to the first through fifth embodiments of the present disclosure, a memory device (100A-100D) comprises an ovonic memory element 150 which comprises a first electrode 151, a second electrode 153; and an ovonic threshold switching material portion 152 located between the first electrode and the second electrode. A first surface of the first electrode 151 that contacts a first surface of the ovonic threshold switching material portion 152 has a greater area than a first surface of the second electrode 153 that contacts a first segment 152F of a second surface of the ovonic threshold switching material portion 152.

In one embodiment, the first surface of the first electrode has a greater lateral dimension along a first horizontal direction (hd1, d1) than the first surface of the second electrode.

In the first through fifth embodiments, the first electrode is located above the second electrode. In one configuration, the first surface of the ovonic threshold switching material portion 152 comprises a bottom surface; the second surface of the ovonic threshold switching material portion 152 comprises a top surface; the first surface of the first electrode 151 comprises a top surface; and the first surface of the second electrode 153 comprises a bottom surface. In another configuration, the first surface of the ovonic threshold switching material portion 152 comprises a top surface; the second surface of the ovonic threshold switching material portion 152 comprises a bottom surface; the first surface of the first electrode 151 comprises a bottom surface; and the first surface of the second electrode 153 comprises a top surface.

In various embodiments described above, the ovonic threshold switching material portion may have a cylindrical, rectangular frustrum or inverted frustum shape.

In the sixth embodiment, a memory device is provided, which comprises: a first alternating stack AS1 of first insulating rails 140 and first electrically conductive rails 130, wherein the first insulating rails 140 and the first electrically conductive rails 130 extend along a first direction d1, and are interlaced along a second direction d2 such that the first insulating rails 140 and the first electrically conductive rails 130 alternate along the second direction d2, and wherein the first alternating stack AS1 comprises a first surface S1 and a second surface S2 that are spaced from each other along a third direction d3 that is perpendicular to the first direction d1 and the second direction d2; a first ovonic memory strip 150S1 comprising a first ovonic memory strip segment 51 containing the ovonic memory element 150 and extending along the second direction d2 and in contact with the first surface S1 of the first alternating stack AS1, and further comprising a second ovonic memory strip segment 52 extending along the second direction d2 and in contact with the second surface S2; and a first conductive line 191 comprising a first conductive line segment 91 extending along the second direction d2 and in contact with the first ovonic memory strip segment 51, and further comprising a second conductive line segment 92 extending along the second direction d2 and in contact with the second ovonic memory strip segment 52.

In the sixth embodiment, the first ovonic memory strip segment 51 and the second ovonic memory strip segment 52 are connected to each other by a first connecting ovonic memory strip segment 56 that extends along the third direction d3. In one embodiment, the first conductive line segment 91 and the second conductive line segment 92 are connected to each other by a first connecting conductive line segment 96 that extends along the third direction d3.

In the sixth embodiment, the device structure further comprises a second alternating stack AS2 of second insulating rails 140 and second electrically conductive rails 130 that is spaced from the first alternating stack AS1 along the third direction d3. The second insulating rails 140 and second electrically conductive rails 130 extend along the second direction d2, and are interlaced along the second direction d2 such that the second insulating rails 140 and the second electrically conductive rails 130 alternate along the second direction d2. The second alternating stack AS2 comprises a third surface S3 and a fourth surface that are spaced from each other along the third direction d3. In one embodiment, the first ovonic memory strip 150S1 further comprises a third ovonic memory strip segment 53 extending along the second direction d2 and in contact with the third surface S3 of the second alternating stack AS2, and further comprises a fourth ovonic memory strip segment 54 extending along the second direction d2 and in contact with the fourth surface S4 of the second alternating stack AS2.

In the sixth embodiment, the device structure further comprises a substrate 8 having a planar surface that is perpendicular to the second direction d2. The first ovonic memory strip 150S1 comprises a connecting ovonic memory strip segment 57 extending along the third direction d3, connecting the second ovonic memory strip segment 52 and the third ovonic memory strip segment 53, and contacting the planar surface of the substrate 8. In one embodiment, the planar surface is in direct contact with the first alternating stack AS1 and the second alternating stack AS2. In one embodiment, the first conductive line 191 comprises a third conductive line segment 93 extending along the second direction d2 and in contact with the third ovonic memory strip segment 53, and further comprises a fourth conductive line segment 94 extending along the second direction d2 and in contact with the fourth ovonic memory strip segment 54.

In the sixth embodiment, the device structure comprises a second ovonic memory strip 150S2 comprising an additional first ovonic memory strip segment 51 extending along the second direction d2 and in contact with the first surface S1 of the first alternating stack AS1, and further comprising an additional second ovonic memory strip segment 52 extending along the second direction d2 and in contact with the second surface S2, wherein the second ovonic memory strip 150S2 is spatially offset from the first ovonic memory strip 150S1 along the first direction d1.

In the sixth embodiment, the device structure further comprises a second conductive line 192 comprising an additional first conductive line segment 91 extending along the second direction d2 and in contact with the additional first ovonic memory strip segment 51, and further comprises an additional second conductive line segment 92 extending along the second direction d2 and in contact with the additional second ovonic memory strip segment 52. The second conductive line 192 is spatially offset from the first conductive line 191 along the first direction d1 by a same spatial offset distance as a spatial offset distance of the second ovonic memory strip 150S2 relative to the first ovonic memory strip 150S1.

In the sixth embodiment, the first ovonic memory strip 150S1 comprises a stack of an ovonic threshold switching material strip 152S and a second electrode strip 153S. In one embodiment, the second electrode strip 153S comprises a stack of a second carbon-based electrode material layer 153C and a second metallic material layer 153M.

In the method of the sixth embodiment, a first ovonic memory strip 150S1 can be formed over the first alternating stack AS1. The first ovonic memory strip 150S1 comprises a first ovonic memory strip segment 51 extending along the second direction d2 and in contact with the first surface S1 of the first alternating stack AS1, and further comprises a second ovonic memory strip segment 52 extending along the second direction d2 and in contact with the second surface S2. A first conductive line 191 can be formed over the first ovonic memory strip 150S1. The first conductive line 191 comprises a first conductive line segment 91 extending along the second direction d2 and in contact with the first ovonic memory strip segment 51, and further comprises a second conductive line segment 92 extending along the second direction d2 and in contact with the second ovonic memory strip segment 52.

In the sixth embodiment, the substrate 8 comprises a planar top surface that is perpendicular to the second direction d2. In one embodiment, a second alternating stack AS2 of second insulating rails 140 and second electrically conductive rails 130 can be formed over the substrate 8. In one embodiment, the second alternating stack AS2 extends along the first direction d1 and is spaced from the first alternating stack AS1 along the third direction d3. In one embodiment, the first ovonic memory strip 150S1 and the first conductive line 191 are formed over the second alternating stack AS2.

In the sixth embodiment, a second ovonic memory strip 150S2 can be formed over the first alternating stack AS1. The second ovonic memory strip 150S2 comprises an additional first ovonic memory strip segment 51 extending along the second direction d2 and in contact with the first surface S1 of the first alternating stack AS1, and further comprises an additional second ovonic memory strip segment 52 extending along the second direction d2 and in contact with the second surface S2. The second ovonic memory strip 150S2 is spatially offset from the first ovonic memory strip 150S1 along the first direction d1. A second conductive line 192 can be formed over the second ovonic memory strip 150S2. The second conductive line 192 comprises an additional first conductive line segment 91 extending along the second direction d2 and in contact with the additional first ovonic memory strip segment 51, and further comprises an additional second conductive line segment 92 extending along the second direction d2 and in contact with the additional second ovonic memory strip segment 52. The second conductive line 192 is spatially offset from the first conductive line 191 along the first direction d1 by a same spatial offset distance as a spatial offset distance of the second ovonic memory strip 150S2 relative to the first ovonic memory strip 150S1.

The OTS memory elements of various embodiments of the present disclosure can improve a memory (i.e., read/write) window for OTS devices when there is an asymmetry between the electrode areas which contact opposite surfaces of the ovonic threshold switching material portion. The memory window is enhanced when there is at least a 10 nm difference between the lateral dimensions of the smaller area electrode and the larger area electrode. The enhancement may be provided in cases where the ovonic threshold switching material portion has a frustum shape, a cylindrical shape or a rectangular shape.

According to an aspect of the present disclosure, electrode size asymmetry can further increase the ΔVₜₕ without the need for extremely high parallel resistance. For example, embodiment OTS devices with asymmetric electrode areas provide lower Vₜₕ values without a polarity change (“+to +” or “−to −”), and a higher Vₜₕ value if there was polarity change (+to −) prior to a Vᵢₙ measurement. In one example, ΔVᵢₙ value may be as high as about 0.8 V (which is about 25% of Vₜₕ). The OTS devices of the embodiments of the present disclosure that include asymmetric electrode sizes exhibit significantly enhanced memory effects compared to OTS devices having the same size electrodes contacting opposite surfaces of the ovonic threshold switching material portion. This enhancement is advantageous because threshold voltage tends to change during use.

The memory arrays of the embodiments of the present disclosure may be implemented as cross-point arrays, either as a two-dimensional memory array or a three-dimensional memory array. The memory arrays of the embodiments of the present disclosure employ self-selective OTS-only cross-point memory cells in which the ovonic threshold switching material portion acts as a memory element which stores data and simultaneously acts as a steering element. Thus, the memory arrays of the embodiments of the present disclosure do not require an additional steering element.

Although the foregoing refers to particular preferred embodiments, it will be understood that the disclosure is not so limited. It will occur to those of ordinary skill in the art that various modifications may be made to the disclosed embodiments and that such modifications are intended to be within the scope of the disclosure. Compatibility is presumed among all embodiments that are not alternatives of one another. The word “comprise” or “include” contemplates all embodiments in which the word “consist essentially of” or the word “consists of” replaces the word “comprise” or “include,” unless explicitly stated otherwise. Whenever two or more elements are listed as alternatives in a same paragraph of in different paragraphs, a Markush group including a listing of the two or more elements is also impliedly disclosed. Whenever the auxiliary verb “can” is employed in this disclosure to describe formation of an element or performance of a processing step, an embodiment in which such an element or such a processing step is not performed is also expressly contemplated, provided that the resulting apparatus or device can provide an equivalent result. As such, the auxiliary verb “can” as applied to formation of an element or performance of a processing step should also be interpreted as “may” or as “may, or may not” whenever omission of formation of such an element or such a processing step is capable of providing the same result or equivalent results, the equivalent results including somewhat superior results and somewhat inferior results. Where an embodiment employing a particular structure and/or configuration is illustrated in the present disclosure, it is understood that the present disclosure may be practiced with any other compatible structures and/or configurations that are functionally equivalent provided that such substitutions are not explicitly forbidden or otherwise known to be impossible to one of ordinary skill in the art. If publications, patent applications, and/or patents are cited herein, each of such documents is incorporated herein by reference in their entirety.

What is claimed is:

1. A memory device comprising an ovonic memory element, wherein the ovonic memory element comprises:
a first electrode;
a second electrode; and
an ovonic threshold switching material portion located between the first electrode and the second electrode, wherein a first surface of the first electrode that contacts a first surface of the ovonic threshold switching material portion has a greater area than a first surface of the second electrode that contacts a first segment of a second surface of the ovonic threshold switching material portion.

2. The memory device of claim 1, wherein the first surface of the first electrode has a greater lateral dimension along a first horizontal direction than the first surface of the second electrode.

3. The memory device of claim 1, wherein the first electrode is located above the second electrode.

4. The memory device of claim 3, wherein:
the first surface of the ovonic threshold switching material portion comprises a bottom surface;
the second surface of the ovonic threshold switching material portion comprises a top surface;
the first surface of the first electrode comprises a top surface; and
the first surface of the second electrode comprises a bottom surface.

5. The memory device of claim 3, wherein:
the first surface of the ovonic threshold switching material portion comprises a top surface;
the second surface of the ovonic threshold switching material portion comprises a bottom surface;
the first surface of the first electrode comprises a bottom surface; and
the first surface of the second electrode comprises a top surface.

6. The memory device of claim 1, further comprising a dielectric spacer contacting a sidewall of the second electrode and a second segment of the second surface of the ovonic threshold switching material portion.

7. The memory device of claim 6, wherein an outer sidewall of the dielectric spacer is vertically coincident with a sidewall of the ovonic threshold switching material portion and with a sidewall of the first electrode.

8. The memory device of claim 6, wherein:
the first segment of the second surface of the ovonic threshold switching material portion comprises a center segment of the second surface of the ovonic threshold switching material portion;
the dielectric spacer laterally surrounds the second electrode and has a tubular configuration; and
the second segment of the second surface of the ovonic threshold switching material portion comprises an annular surface having a uniform lateral spacing of at least 4 nm between an inner periphery and an outer periphery.

9. The memory device of claim 6, further comprising:
an additional ovonic memory element that is laterally spaced from the ovonic memory element along a second horizontal direction and comprises an additional first electrode, an additional second electrode, and an additional ovonic threshold switching material portion located between the additional first electrode and the additional second electrode;
the first electrode and the second electrode have a same lateral extent along the second horizontal direction; and
the dielectric spacer contacts a sidewall of the additional second electrode and a segment of a top surface of the additional ovonic threshold switching material portion.

10. The memory device of claim 1, wherein the ovonic threshold switching material portion has a cylindrical shape.

11. The memory device of claim 1, wherein the ovonic threshold switching material portion has a rectangular shape.

12. The memory device of claim 1, wherein the ovonic threshold switching material portion has a frustum shape or an inverted frustum shape.

13. A memory device, comprising:
a first alternating stack of first insulating rails and first electrically conductive rails, wherein the first insulating rails and the first electrically conductive rails extend along a first direction, and are interlaced along a second direction such that the first insulating rails and the first electrically conductive rails alternate along the second direction, and wherein the first alternating stack comprises a first surface and a second surface that are spaced from each other along a third direction that is perpendicular to the first direction and the second direction;
a first ovonic memory strip comprising a first ovonic memory strip segment containing the an ovonic memory element, the first ovonic memory strip segment extending along the second direction and in contact with the first surface of the first alternating stack, and further comprising a second ovonic memory strip segment extending along the second direction and in contact with the second surface; and
a first conductive line comprising a first conductive line segment extending along the second direction and in contact with the first ovonic memory strip segment, and further comprising a second conductive line segment extending along the second direction and in contact with the second ovonic memory strip segment.

14. The memory device of claim 13, wherein:
the first ovonic memory strip segment and the second ovonic memory strip segment are connected to each other by a first connecting ovonic memory strip segment that extends along the third direction; and
the first conductive line segment and the second conductive line segment are connected to each other by a first connecting conductive line segment that extends along the third direction.

15. The memory device of claim 13, further comprising a second alternating stack of second insulating rails and second electrically conductive rails that is spaced from the first alternating stack along the third direction, wherein the second insulating rails and second electrically conductive rails extend along the second direction, and are interlaced along the second direction such that the second insulating rails and the second electrically conductive rails alternate along the second direction, and wherein the second alternating stack comprises a third surface and a fourth surface that are spaced from each other along the third direction.

16. The memory device of claim 13, wherein:
the first surface of the ovonic threshold switching material portion comprises an outer surface; and
the second surface of the ovonic threshold switching material portion comprises an inner surface.

17. A method of forming a memory device, comprising:
forming first electrically conductive lines laterally extending along a first horizontal direction;
forming a first electrode layer over the first electrically conductive lines;
forming an ovonic threshold switching material layer over the first electrode layer;
forming a second electrode layer over the ovonic threshold switching material layer;
patterning the second electrode layer into a two-dimensional array of second electrodes;
forming sidewall spacers on at least one sidewall of the second electrodes;
patterning the ovonic threshold switching material layer and the first electrode layer into a two-dimensional array of ovonic threshold switching material portions and first electrodes using the two-dimensional array of second electrodes and the sidewall spacers as a mask; and
forming second electrically conductive lines laterally extending along a second horizontal direction over the two-dimensional array of ovonic threshold switching material portions.

18. The method of claim 17, wherein the first electrodes have a larger area than the second electrodes.

19. A method of forming a device structure, comprising:
forming a first alternating stack of first insulating rails and first electrically conductive rails over a substrate, wherein the first insulating rails and first electrically conductive rails extend along a first direction, and are interlaced along a second direction such that the first insulating rails and the first electrically conductive rails alternate along the second direction, and wherein the first alternating stack comprises a first surface and a second surface that are spaced from each other along a third direction that is perpendicular to the first direction and the second direction;
forming a first ovonic memory strip over the first alternating stack, wherein the first ovonic memory strip comprises a first ovonic memory strip segment extending along the second direction and in contact with the first surface of the first alternating stack, and further comprises a second ovonic memory strip segment extending along the second direction and in contact with the second surface; and
forming a first conductive line over the first ovonic memory strip, wherein the first conductive line comprises a first conductive line segment extending along the second direction and in contact with the first ovonic memory strip segment, and further comprises a second conductive line segment extending along the second direction and in contact with the second ovonic memory strip segment.

20. The method of claim 19, wherein:
the substrate comprises a planar top surface that is perpendicular to the second direction;
the method comprises forming a second alternating stack of second insulating rails and second electrically conductive rails over the substrate;
the second alternating stack extends along the first direction and is spaced from the first alternating stack along the third direction; and
the first ovonic memory strip and the first conductive line are formed over the second alternating stack.
